(19) United States
(12) Patent Application Publication
(10) Pub. No.: US 2025/0190116 A1
(43) Pub. Date: Jun. 12, 2025

(54) MEMORY SYSTEM, OPERATING METHOD OF MEMORY CONTROLLER, AND MEMORY DEVICE

(71) Applicant: SAMSUNG ELECTRONICS CO., LTD., Suwon-si (KR)

(72) Inventors: Hoon Shin, Suwon-si (KR); Minchur Shin, Suwon-si (KR); Ki-Heung Kim, Suwon-si (KR); Hoseok Seol, Suwon-si (KR)

(21) Appl. No.: 18/970,654

(22) Filed: Dec. 5, 2024

(30) Foreign Application Priority Data
Dec. 6, 2023 (KR) 10-2023-0176034
May 28, 2024 (KR) 10-2024-0069559

(51) Int. Cl. G06F 3/06; G11C 11/406; G11C 11/4078

(52) U.S. Cl. CPC G06F 3/0613; G06F 3/0653; G06F 3/0673; G11C 11/406; G11C 11/4078

(57) ABSTRACT

Disclosed is a memory system which includes a memory device that includes a memory cell array and a notification circuit, and a memory controller that transmits a refresh management (RFM) command to the memory device, based on a number of occurrences of bank activation of a bank included in the memory cell array reaching a threshold. The memory controller controls a transmission frequency of the RFM command, based on a notification obtained through the notification circuit. The notification includes at least one of a row hammer risk for rows included in the bank or temperature information including a temperature range of the memory device.

### CROSS-REFERENCE TO RELATED APPLICATIONS

This application claims priority under 35 U.S.C. § 119 to Korean Patent Application Nos. 10-2023-0176034 filed on Dec. 6, 2023, and 10-2024-0069559 filed on May 28, 2024, in the Korean Intellectual Property Office, the disclosures of which are incorporated by reference herein in their entireties.

### BACKGROUND

Implementations of the present disclosure described herein relate to a memory system, an operating method of a memory controller, and a memory device.

A row hammer refers to a phenomenon in which, when a row (e.g., an aggressor row) of a dynamic random access memory (DRAM) is frequently accessed, data of a row(s) (e.g., a victim row(s)) physically adjacent to the corresponding row changes.

### SUMMARY

Implementations of the present disclosure provide a memory system capable of variably controlling the transmission frequency of an RFM command depending on a situation of a memory device, an operating method of a memory controller, and a memory device.

The row hammer issue may be solved by performing a row hammer refresh operation on risky rows at an appropriate time. Nowadays, as DRAM is manufactured by using nano-scale manufacturing processes, the row hammer issue has become serious. Accordingly, a refresh management (RFM) interface is being introduced to provide an additional row hammer refresh opportunity to the DRAM. When the number of times of activation for each bank of the DRAM reaches a fixed specific threshold value, a memory controller issues an RFM command, and the DRAM may perform a row hammer refresh operation based on the received RFM command.

In this case, the uniform issuance of the RFM command according to one fixed standard may cause the unnecessary transmission of the RFM command, resulting in the damage of efficiency of the bandwidth of the memory system or the reduction of performance of the memory system. The present disclosure is directed to technology for issuing the RFM command more appropriately in consideration of the situation of the DRAM.

According to implementations, a memory system may include a memory device that includes a memory cell array and a notification circuit, and a memory controller configured to transmit a refresh management (RFM) command to the memory device, based on a number of occurrences of bank activation of a bank included in the memory cell array reaching a threshold. The memory controller is configured to control a transmission frequency of the RFM command, based on a notification obtained through the notification circuit. The notification includes at least one of a row hammer risk for rows included in the bank or temperature information including a current temperature of the memory device.

Also, the bank may include a plurality of rows arranged in a row direction, and a plurality of count cells configured to store count data associated with the number of occurrences of activation of each of the plurality of rows, and risk information related to the row hammer risk indicates that the count data reached a reference count.

In addition, the notification circuit may include at least one of an alert pin or a first register. The alert pin may transmit a risk signal in response to the count data stored in at least one count cell among the plurality of count cells reaching the reference count to indicate a risky situation. The first register may store flag data in response to the count data stored in at least one count cell among the plurality of count cells reaching the reference count to indicate the risky situation.

Furthermore, the memory controller may obtain the row hammer risk, based on the flag data stored in the first register or the risk signal transmitted by the alert pin.

Besides, the memory controller may operate in one of a first mode or a second mode based on the row hammer risk. In the first mode, the memory controller may maintain operation without transmitting the RFM command irrespective of the number of occurrences of bank activation, and in the second mode, the memory controller may transmit the RFM command based on the number of occurrences of bank activation reaching the threshold.

Also, the memory controller may operate in the second mode based on the flag data including first data indicative of the risky situation and may otherwise operate in the first mode.

In addition, the memory controller may perform a read operation on the first register to obtain the row hammer risk based on the number of occurrences of bank activation reaching the threshold.

Furthermore, the memory controller may perform, in the first mode, a read operation on the first register based on the number of occurrences of bank activation reaching the threshold, and switch the operation mode from the first mode to the second mode based on obtaining the flag data indicating the risky situation, and switch the operation mode from the second mode back to the first mode in response to transmitting a set number of RFM commands to perform the read operation on the first register.

Besides, the memory controller may operate in the second mode when the alert signal is applied through the alert pin and may operate in the first mode when the obtained flag data does not indicate the risky situation.

Also, based on the risk signal being applied through the alert pin while operating in the first mode, the memory controller may perform the read operation on the first register after operating in the second mode until the RFM command is transmitted no more than a predefined number of times.

In addition, the memory controller may set an operation mode to one of a third mode or a fourth mode based on the row hammer risk. In the third mode, the memory controller may transmit the RFM command based on the number of occurrences of bank activation reaching a first threshold, and in the fourth mode, the memory controller may transmit the RFM command based on the number of occurrences of bank activation reaching a second threshold. The second threshold may be smaller in value than the first threshold.

Furthermore, the memory controller may set the operation mode to the fourth mode based on the risk signal being applied through the alert pin or based on obtaining the flag data indicating the risky situation is obtained through a read operation of the first register while operating in the third mode.

Besides, the memory controller may perform the read operation on first register based on the RFM command being transmitted no more than a predefined number of times while operating in the fourth mode and may otherwise operate in the third mode.

Also, the notification circuit may include a second register that stores temperature information of the memory device, and the memory controller may obtain the temperature information based on a read operation of the second register and may adjust the threshold based on the obtained temperature information.

In addition, the memory device may operate in a first refresh interval time for a first temperature range and may have a second refresh interval time shorter than the first refresh interval time for a second temperature range. The memory controller may transmit the RFM command based on the number of occurrences of bank activation reaching a third threshold in the first temperature range and may transmit the RFM command based on the number of occurrences of bank activation reaching a fourth threshold in the second temperature range. The third threshold may be smaller in value than the fourth threshold.

Furthermore, the memory controller may count the number of occurrences of bank activation and may sum a bank activation time of the bank which is based on the transmitted activate command, in response to an activate command being transmitted to the bank, and may transmit the RFM command based on the number of occurrences of bank activation reaching the threshold or based on the summed bank activation time reaching a time threshold.

Besides, the memory controller may increase the number of occurrences of bank activation as much as a first value based on the activate command transmitted to the bank being equal to or smaller than a reference time and may increase the number of occurrences of bank activation as much as a second value greater than the first value based on the bank activation time exceeding the reference time.

According to implementations, an operating method of a memory controller which controls a memory device may include transmitting a refresh management (RFM) command to the memory device based on a number of occurrences of bank activation of a bank of the memory device reaching a threshold, obtaining a notification including at least one of information about a row hammer risk of each of rows included in the bank of the memory device or temperature information including a temperature range of the memory device, and controlling a transmission frequency of the RFM command based on the notification.

Also, the controlling of the transmission frequency of the RFM command may include selectively transmitting the RFM command based on the notification or adjusting the threshold based on the notification.

According to implementations, a memory device may include a memory cell array that includes a bank, a row hammer management circuit, and a notification circuit that includes at least one of an alert pin or a register. The bank may include a plurality of rows arranged in a row direction, and a plurality of count cells that store count data associated with a number of occurrences of activation of each of the plurality of rows. The row hammer management circuit may manage the count data for each of the plurality of rows and may store flag data indicating a risky situation in the register and apply a risk signal indicating the risky situation to the alert pin based on the count data stored in at least one of the plurality of count cells reaching a reference count.

### BRIEF DESCRIPTION OF THE FIGURES

The above and other objects and features of the present disclosure will become apparent by describing in detail implementations thereof with reference to the accompanying drawings.

FIG. 1 is a block diagram of a memory system according to implementations of the present disclosure.

FIG. 2A is a block diagram of a memory device according to implementations of the present disclosure.

FIG. 2B is a block diagram of a memory device according to implementations of the present disclosure.

FIG. 3A is a diagram illustrating an example of a bank according to implementations of the present disclosure.

FIG. 3B is a diagram illustrating an example of a bank in which count cells are included in a count cell area.

FIG. 3C is a diagram illustrating an example of a bank in which count cells and parity cells are included in a count cell area.

FIG. 4 is a block diagram illustrating a memory device according to implementations of the present disclosure in detail.

FIG. 5A is a block diagram of a memory controller according to implementations of the present disclosure.

FIG. 5B is a flowchart illustrating an operating method of a memory controller according to implementations of the present disclosure.

FIG. 6 is a block diagram illustrating a configuration of RFM control logic according to implementations of the present disclosure.

FIG. 7 is a flowchart illustrating an operating method of a memory controller according to implementations of the present disclosure.

FIG. 8 is a flowchart illustrating an operating method of a memory controller according to implementations of the present disclosure.

FIG. 9 is a flowchart illustrating an operating method of a memory controller according to implementations of the present disclosure.

FIG. 10 is a diagram for describing an operation in which an RFM command is selectively transmitted, according to implementations of the present disclosure.

FIG. 11 is a flowchart illustrating an operating method of a memory controller according to implementations of the present disclosure.

FIG. 12 is a flowchart illustrating an operating method of a memory controller according to implementations of the present disclosure.

FIG. 13 is a flowchart illustrating an operating method of a memory controller according to implementations of the present disclosure.

FIG. 14 is a diagram for describing an operation in which a BAT value is adjusted, according to implementations of the present disclosure.

FIG. 15 is a block diagram of a memory device according to implementations of the present disclosure.

FIG. 16 is a block diagram illustrating RFM control logic according to implementations of the present disclosure.

FIG. 17 is a diagram for describing an example of a BAT value for each temperature range according to implementations of the present disclosure.

FIG. 18 is a diagram for describing an operation in which a BAT value is adjusted, according to implementations of the present disclosure.

FIG. 19 is a block diagram of RFM control logic according to implementations of the present disclosure.

FIG. 20 is a diagram for describing a bank activation time according to implementations of the present disclosure.

FIG. 21 is a flowchart illustrating an operating method of a memory controller according to implementations of the present disclosure.

FIG. 22A is a flowchart illustrating an operating method of a memory controller according to implementations of the present disclosure.

FIG. 22B is a flowchart illustrating an operating method of a memory controller according to implementations of the present disclosure.

FIG. 23 is a diagram for describing an operation in which the RFM command is transmitted in consideration of the bank activation time, according to implementations of the present disclosure.

### DETAILED DESCRIPTION

Hereinafter, various implementations of the present disclosure will be described in detail with reference to the accompanying drawings to such an extent that one skilled in the art to which the present disclosure belongs may easily carry the present disclosure.

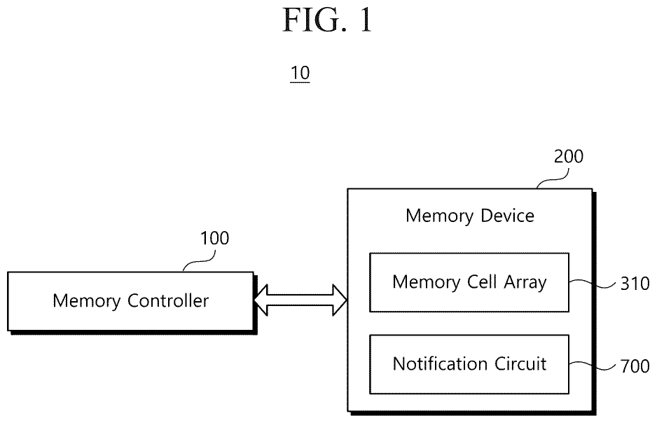

FIG. 1 is a block diagram of a memory system according to implementations of the present disclosure.

According to implementations of the present disclosure, a memory device 200 may include a notification circuit 700 for notifying a memory controller 100 of notification associated with the situation of the memory device 200. In implementations, the notification may include at least one of information about a row hammer risk of rows included in each bank of a memory cell array 310 or temperature information indicating a current temperature range including a current temperature of the memory device 200.

The memory controller 100 may transmit a refresh management (RFM) command to the memory device 200, based on whether a number of times activation of a bank included in the memory device 200 reaches a threshold. In implementations, the memory controller 100 may variably control the transmission frequency of the RFM command depending on information associated with the situation of the memory device 200. For example, based on the notification obtained through the notification circuit 700, the memory controller 100 may selectively control whether to transmit the RFM command or may adjust the threshold associated with the transmission of the RFM command. Also, the memory controller 100 may transmit the RFM command further in consideration of an activation time of a bank included in the memory device 200. Accordingly, the efficiency of bandwidth of a memory system 10 and the performance of the memory system 10 may be improved.

The description will be given in detail with reference to FIG. 1. Referring to FIG. 1, the memory system 10 may include the memory controller 100 and the memory device 200.

The memory device 200 may receive data from the memory controller 100 and may store the received data. The memory device 200 may read the stored data in response to a request of the memory controller 100 and may transmit the read data to the memory controller 100.

In implementations, the memory device 200 may be a memory device including volatile memory cells. For example, the memory device 200 may include various dynamic random access memory (DRAM) devices such as a double data rate synchronous DRAM (DDR SDRAM), a DDR2 SDRAM, a DDR3 SDRAM, a DDR4 SDRAM, a DDR5 SDRAM, a DDR6 SDRAM, a low power double data rate (LPDDR) SDRAM, an LPDDR2 SDRAM, an LPDDR3 SDRAM, an LPDDR4 SDRAM, an LPDDR4X SDRAM, an LPDDR5 SDRAM, a graphics double data rate synchronous graphics random access memory (GDDR SGRAM), a GDDR2 SGRAM, a GDDR3 SGRAM, a GDDR4 SGRAM, a GDDR5 SGRAM, and a GDDR6 SGRAM.

Also, in implementations, the memory device 200 may be a stacked memory device, in which DRAM dies are stacked, such as a high bandwidth memory (HBM), an HBM2, or an HBM3.

In addition, in implementations, the memory device 200 may be a memory module such as a dual in-line memory module (DIMM). For example, the memory device 200 may be a registered DIMM (RDIMM), a load reduced DIMM (LRDIMM), an unbuffered DIMM (UDIMM), a fully buffered DIMM (FB-DIMM), or a small outline DIMM (SO-DIMM). However, this is provided as an example, and the memory device 200 may be any other memory module such as a single in-line memory module (SIMM).

Also, in implementations, the memory device 200 may be an SRAM device, a NAND flash memory device, a NOR flash memory device, an RRAM device, an FRAM device, a PRAM device, a TRAM device, an MRAM device, etc.

The memory device 200 may include the memory cell array 310 and the notification circuit 700.

The memory cell array 310 may include a plurality of banks. Each of the plurality of banks may include memory cells for storing data. For convenience of description, in the specification, it is assumed that each bank includes DRAM cells. However, this is provided as an example, and each of the plurality of banks may be implemented to include any other volatile memory cells in addition to the DRAM cells. Also, according to implementations, the plurality of banks may be implemented to include the same kind of memory cells or may be implemented to include different kinds of memory cells.

Each of the plurality of banks may include a plurality of rows. Herein, the row may refer to a conductive line which is disposed to extend in a row direction and is electrically connected to memory cells. For example, one row may refer to one word line disposed to extend in the row direction. However, this is provided as an example. According to implementations, one row may refer to a plurality of word lines disposed to extend in the row direction.

The notification circuit 700 may notify the memory controller 100 of notification associated with the situation of the memory device 200. For example, the memory device 200 may notify the memory circuit of row hammer risks of rows included in a bank of the memory cell array 310 through the notification circuit 700. In implementations, the row hammer risk may indicate whether count data associated with the number of times of activation of each row of the bank reaches a reference count. Also, the memory device 200 may notify temperature information about a temperature range, to which a current temperature of the memory device 200 belongs, through the notification circuit 700.

Meanwhile, when the memory device 200 has a row hammer refresh opportunity, the memory device 200 may perform the row hammer refresh operation. In implementations, the row hammer refresh opportunity may include the case where a refresh (REF) command is applied from the memory controller 100 or the case where the RFM command is applied from the memory controller 100.

The memory controller 100 may control the memory device 200. For example, the memory controller 100 may control the memory device 200 depending on a request of a processor supporting various applications such as a server application, a personal computer (PC) application, and a mobile application. For example, the memory controller 100 may be included in a host device including a processor and may control the memory device 200 depending on a request of the processor.

To control the memory device 200, the memory controller 100 may transmit a command and/or an address to the memory device 200. Also, the memory controller 100 may transmit data to the memory device 200 or may receive data from the memory device 200.

The memory controller 100 may count the number of times of bank activation. For example, when the memory controller 100 transmits an activate (ACT) command for a specific bank of the memory device 200, the memory controller 100 may increase the number of times of bank activation as much as “1”. However, the present disclosure is not limited thereto. Also, the memory controller 100 may transmit the RFM command to the memory device 200, based on whether the number of occurrences of bank activation reaches the threshold. In implementations, the threshold may be a bank activation threshold (BAT). Below, for convenience, the description will be given under the condition that the threshold of the number of times of bank activation used as a criterion of the transmission of the RFM command refers to the “BAT”.

In implementations, the memory controller 100 may control the transmission frequency of the RFM command based on the notification obtained through the notification circuit 700.

According to implementations, the memory controller 100 may selectively transmit the RFM command based on the row hammer risk. For example, the memory controller 100 may operate in a first mode or a second mode, based on the row hammer risk. In the first mode, even though the number of times of bank activation reaches the BAT, the memory controller 100 may not transmit the RFM command; in the second mode, when the number of times of bank activation reaches the BAT, the memory controller 100 may transmit the RFM command. In detail, the memory controller 100 may identify whether the memory device 200 is in a risky situation in association with a row hammer, based on the row hammer risk obtained through the notification circuit 700. Accordingly, in implementations, the memory controller 100 may operate in the first mode when a current situation is not a risky situation and may operate in the second mode when a current situation is a risky situation. As the memory controller 100 operates in the first mode or the second mode depending on the current situation, the transmission frequency of the RFM command may be variably controlled.

Alternatively, according to implementations, the memory controller 100 may adjust the BAT, based on the row hammer risk. For example, the memory controller 100 may operate in a third mode or a fourth mode, based on the row hammer risk. In the third mode, when the number of times of bank activation reaches a first threshold (hereinafter referred to as “BAT1”), the memory controller 100 may transmit the RFM command; in the fourth mode, when the number of times of bank activation reaches a second threshold (hereinafter referred to as “BAT2”), the memory controller 100 may transmit the RFM command. In implementations, the BAT2 may be smaller in value than the BAT1. In detail, the memory controller 100 may identify whether the memory device 200 is in a risky situation in association with a row hammer, based on the row hammer risk obtained through the notification circuit 700. Accordingly, in the above example, as the memory controller 100 operates in the third mode when a current situation is not a risky situation and operates in the fourth mode when a current situation is a risky situation, the memory controller 100 may variably control the transmission frequency of the RFM command.

Alternatively, according to implementations, the memory controller 100 may adjust the BAT based on temperature information including a temperature range of the memory device 200. The memory device 200 may have different refresh interval times (tREFI) depending on temperature ranges. In implementations, the refresh interval time refers to a period where the REF command is transmitted from the memory controller 100 to the memory device 200. For example, the memory device 200 may have a first refresh interval time in a first temperature range and may have a second refresh interval time shorter than the first refresh interval time in a second temperature range higher than the first temperature range. In this case, because the transmission period of the REF command is relatively long in a low temperature range, the row hammer refresh opportunity based on the REF command may also decrease in the low temperature range. That is, because the degree of loss of the row hammer refresh opportunity based on the REF command varies with a temperature range, the number of necessary RFM commands may also vary with a temperature range to compensate for the loss of the row hammer refresh opportunity.

In implementations, under the condition that the temperature range of the memory device 200 is the first temperature range, when the number of times of bank activation reaches a third threshold (hereinafter referred to as “BAT3”), the memory controller 100 may transmit the RFM command; under the condition that the temperature range of the memory device 200 is the second temperature range, when the number of times of bank activation reaches a fourth threshold (hereinafter referred to as “BAT4”), the memory controller 100 may transmit the RFM command. In implementations, the BAT3 may be smaller in value than the BAT4. That is, the memory controller 100 may variably control the transmission frequency of the RFM command based on temperature information including the temperature range of the memory device 200. In this case, the transmission frequency of the RFM command may be relatively high in the first temperature range and may be relatively low in the second temperature range. Accordingly, the loss of the row hammer refresh opportunity based on the REF command may be appropriately compensated for depending on a temperature range. In particular, the burden of the memory controller 100 for the transmission of the RFM command may be reduced in a relatively high temperature range.

Meanwhile, the memory controller 100 may transmit the RFM command further in consideration of a bank activation time of a bank included in the memory cell array 310. In this case, the transmission frequency of the RFM command may be variably controlled based on the bank activation time.

According to implementations, in response to whether the memory controller 100 transmits the ACT command for a specific bank of the memory device 200, the memory controller 100 may count the number of times of bank activation of the corresponding bank and may sum the bank activation time of the corresponding bank based on the transmitted ACT command. In implementations, the bank activation time may refer to a time from a point in time when the ACT command is transmitted to a point in time when a precharge (PRE) command following the ACT command is transmitted, but the present disclosure is not limited thereto. Accordingly, when the number of times of bank activation reaches the BAT or the summed bank activation time reaches a threshold, the memory controller 100 may transmit the RFM command to the memory device 200. Below, for convenience, the description of a threshold associated with the bank activation time is referred to as a “bank activation time threshold (BATT)”. In this case, even though the number of times of bank activation does not reach the BAT, when the bank activation time reaches the BATT, the RFM command may be transmitted.

Alternatively, according to implementations, when the bank activation time is equal to or smaller than a reference time, the memory controller 100 may increase the number of times of bank activation as much as a first value (e.g., “1”); when the bank activation time exceeds the reference time, the memory controller 100 may increase the number of times of bank activation as much as a second value (e.g., “2”) greater than the first value. Accordingly, when the number of times of bank activation reaches the BAT, the memory controller 100 may transmit the RFM command to the memory device 200. In this case, as the command having the bank activation time exceeding the reference time is more transmitted, the number of times of bank activation may increase more quickly. This may mean that the RFM command is transmitted more frequently.

According to the above implementations in which the bank activation time is further considered, it may be possible to cope with an issue due to a pass gate effect (PGE) phenomenon, that is, an issue that the probability of data loss of a victim row increases as the activation time of a target row increases.

Meanwhile, the implementations described with reference to FIG. 1 may be independently implemented in the memory system 10, but the present disclosure is not limited thereto. For example, at least one embodiment may be implemented together in the memory system 10.

According to the above implementations, the transmission frequency of the RFM command may be variably controlled in consideration of various situations of the memory device 200, such as a row hammer risk, a refresh interval time according to a temperature range, and a PGE phenomenon of a memory cell. Accordingly, the efficiency of bandwidth of a memory system or the performance of the memory system may be improved.

Meanwhile, in the specification, the case where the number of times of bank activation reaches the threshold BAT, BAT1, BAT2, BAT3, or BAT4 may include the case where the increased number of times of bank activation is greater in value than the threshold BAT, BAT1, BAT2, BAT3, or BAT4, in addition to the case where the increased number of times of bank activation coincides with the threshold BAT, BAT1, BAT2, BAT3, or BAT4. That is, due to an abnormal operation or a design change, the case where the increased number of times of bank activation is greater in value than the threshold BAT, BAT1, BAT2, BAT3, or BAT4 may also correspond to the case where the number of times of bank activation reaches the threshold BAT, BAT1, BAT2, BAT3, or BAT4.

For example, due to an abnormal operation of the memory controller 100, the number of times of bank activation which is increased as much as “1” may skip the threshold BAT, BAT1, BAT2, BAT3, or BAT4 and may exceed the threshold BAT, BAT1, BAT2, BAT3, or BAT4. This case may also be included in the case where the number of times of bank activation reaches the threshold BAT, BAT1, BAT2, BAT3, or BAT4. Also, for example, the threshold BAT, BAT1, BAT2, BAT3, or BAT4 may be set to 65, but when the memory controller 100 is designed to increase the number of times of bank activation as much as “2”, the number of times of bank activation which is increased as much as “2” may be directly increased from 64 to 66 without reaching “65”. This case may also be included in the case where the number of times of bank activation reaches the threshold BAT, BAT1, BAT2, BAT3, or BAT4.

Meanwhile, the above content may also be applied to the case where the bank activation time reaches the threshold (BATT). That is, in the specification, the case where the summed bank activation time reaches the threshold BATT may include the case where the summed bank activation time exceeds the threshold BATT, in addition to the case where the summed bank activation time coincides with the threshold BATT.

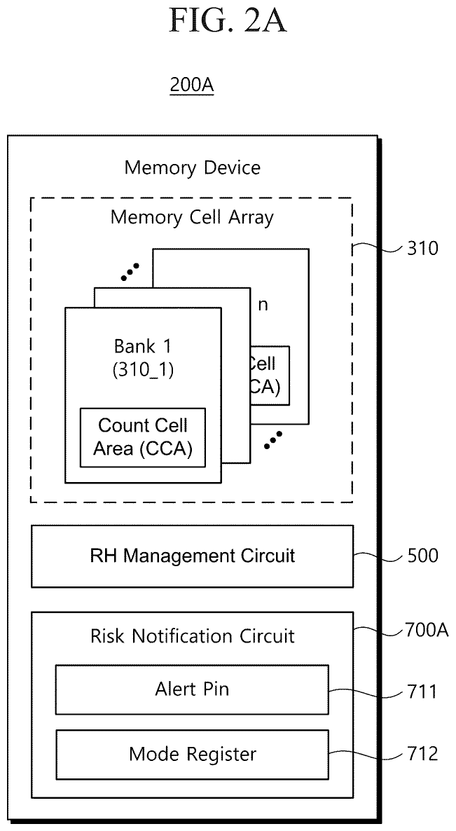

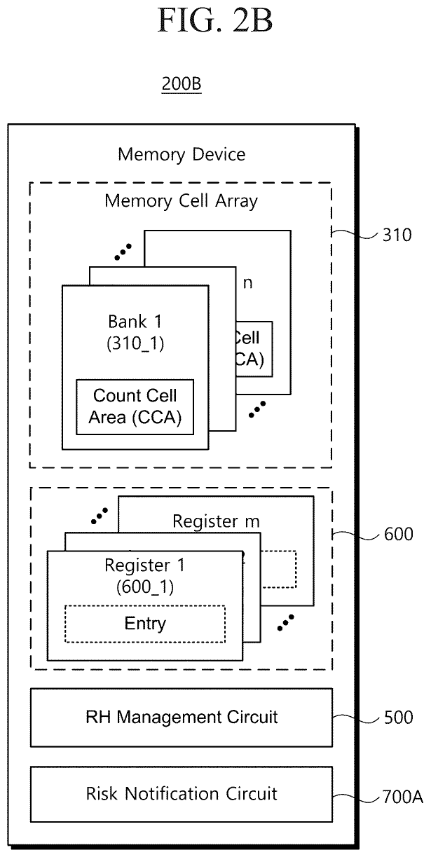

Below, a memory device according to various implementations of the present disclosure will be described with reference to FIGS. 2A to 4. FIG. 2A is a block diagram of a memory device according to implementations of the present disclosure. A memory device 200A of FIG. 2A may be an implementation of the memory device 200 of FIG. 1, but the present disclosure is not limited thereto. In FIG. 2A, the description which is given above in association with components similar to the above components will be omitted or simplified.

Referring to FIG. 2A, the memory device 200A may include the memory cell array 310, a row hammer management circuit 500, and a risk notification circuit 700A.

The memory cell array 310 may include a plurality of banks 310_1 to 310_n, each of which includes memory cells for storing data. Each of the plurality of banks 310_1 to 310_n may include a plurality of rows. Also, each of the plurality of banks 310_1 to 310_n may include a count cell area CCA. The count cell area CCA may include a plurality of count cells, and each of the plurality of count cells may store the number of times of activation of the corresponding row as count data. The count data stored in the count cell may be referred to as “per row activation count data” or “PRAC data”

For example, when a target row is accessed based on the ACT command applied from the memory controller 100, the count data may be read from the count cell corresponding to the target row being the activated state. Afterwards, the read count data may be modified, and the modified count data may be again written in the count cell corresponding to the target row. The number of times of activation of each of the plurality of rows may be stored in the corresponding count cell through the read-modify-write (RMW) operation.

According to implementations, some of memory cells connected to one row may be used as a count cell. In this case, the count cell area CCA may include count cells associated with each of the plurality of rows. Alternatively, according to implementations, some of memory cells connected to one row may be used as a count cell, and others thereof may be used as a parity cell. A parity cell may store parity data for performing an error correction operation on the count data. In this case, the count cell area CCA may include count cells respectively corresponding to the plurality of rows and parity cells for each of the plurality of rows.

Meanwhile, in FIG. 2A, each of the plurality of banks 310_1 to 310_n shows implementations including the count cell area CCA. However, this is provided as an example. According to implementations, some of the plurality of banks 310_1 to 310_n may not include the count cell area CCA. According to implementations, different banks may share the same count cell area CCA. For example, when different banks share the same word line, only any one bank among the different banks may include the count cell area CCA, and the remaining banks may share and use the corresponding count cell area CCA.

The row hammer management circuit 500 may manage the count data associated with each of the plurality of rows, based on a command received from the memory controller 100. For example, when a word line is activated depending on the ACT command received from the memory controller 100, the row hammer management circuit 500 may count the number of times of activation of target row corresponding to the activated word line. Afterwards, the row hammer management circuit 500 may store the count data being the number of times of activation in the count cell associated with the corresponding target row. However, this is provided as an example, and the row hammer management circuit 500 may count the number of times of activation of the target row based on the precharge (PRE) command.

According to implementations, the row hammer management circuit 500 may perform the RMW operation to manage the count data of each of the plurality of rows. Also, according to implementations, the row hammer management circuit 500 may manage the count data of each of the plurality of rows further in consideration of the activation time of the target row. In this case, when the activation time of the target row exceeds the reference time, the row hammer management circuit 500 may further increase the count data additionally.

Meanwhile, the row hammer management circuit 500 may notify the memory controller 100 of the row hammer risk, based on the count data. In implementations, the row hammer risk may indicate whether the count data reach the reference count. Meanwhile, the reference count may be set appropriately by a designer within a process strength of a memory cell. Herein, the process strength may refer to the threshold of the number of times of activation of an aggressor row, within which data of victim rows are not changed, but the present disclosure is not limited thereto.

In detail, the memory device 200A may include the risk notification circuit 700A including at least one of an alert pin 711 or a mode register 712. The alert pin 711 may be electrically connected to the memory controller 100 through an alert signal line. A signal associated with the row hammer risk may be applied to the alert pin 711. Accordingly, the memory controller 100 may identify the row hammer risk of the memory device 200A based on the signal applied to the alert pin 711. Also, the mode register 712 may store flag data associated with the row hammer risk. Accordingly, the memory controller 100 may obtain the flag data stored in the mode register 712 through a mode register read operation and may identify the row hammer risk of the memory device 200A based on the obtained flag data.

For example, when the count data stored in at least one count cell among the plurality of count cells reach the reference count, the row hammer management circuit 500 may apply a risk signal indicating the risky situation to the alert pin 711. Accordingly, when the risk signal is applied to the alert pin 711, the memory controller 100 may identify that the row hammer risk of the memory device 200A reaches a risk level. Also, when the count data stored in at least one count cell among the plurality of count cells reaches the reference count, the row hammer management circuit 500 may store flag data indicating the risky situation in the mode register 712. Accordingly, when the flag data read from the mode register 712 indicates the risky situation, the memory device 200A may identify that the row hammer risk of the memory device 200A reaches a risk level. In this case, according to implementations, the case where the count data reach the reference count may include the case where the count data exceed the reference count, in addition to the case where the count data coincide with the reference count. Meanwhile, when the risk signal is not received through the alert pin 711 and when the flag data read from the mode register 712 does not indicate the risky situation, the memory controller 100 may identify that the row hammer risk of the memory device 200A is low.

The memory controller 100 may variably control the transmission frequency of the RFM command, as described with reference to FIG. 1, based on the signal applied to the alert pin 711 or the flag data stored in the mode register 712.

According to implementations, the memory device 200A may perform the row hammer refresh operation at various opportunities. For example, the memory device 200A may perform the row hammer refresh operation in response to the RFM command received from the memory controller 100. Also, the memory device 200A may perform a normal refresh operation and the row hammer refresh operation in response to the REF command received from the memory controller 100. Also, the memory device 200A may perform the row hammer refresh operation in an idle state or when the background operation is performed. In this case, the memory device 200A may perform the row hammer refresh operation based on the count data stored in a plurality of count cells.

FIG. 2B is a block diagram of a memory device according to implementations of the present disclosure. A memory device 200B of FIG. 2B may be implementations of the memory devices 200 and 200A of FIGS. 1 and 2A, but the present disclosure is not limited thereto. In FIG. 2B, the description which is given above in association with components similar to the above components will be omitted or simplified.

Referring to FIG. 2B, the memory device 200B may include the memory cell array 310, a register group 600, the row hammer management circuit 500, and the risk notification circuit 700A.

According to implementations of the present disclosure, the count data stored in the plurality of count cells may be managed through a register. To this end, the memory device 200B may include the register group 600. The register group 600 may include a plurality of registers 600_1 to 600_m. In this case, one register may correspond to one bank. Alternatively, one register may correspond to a plurality of banks.

Each of the plurality of registers 600_1 to 600_m may store information about some of a plurality of rows included in the corresponding bank. For example, each of the plurality of registers 600_1 to 600_m may store an address and count data, which are associated with a row having relatively great count data from among the plurality of rows included in the corresponding bank.

To this end, the row hammer management circuit 500 may update the register group 600 by using the modified count data of the target row generated through the RMW operation. For example, the row hammer management circuit 500 may select a register, which corresponds to a bank to which the target row belongs, from among registers of the register group 600. Afterwards, the row hammer management circuit 500 may compare addresses and count data of rows managed in a selected register with the address and the modified count data of the target row. Based on a comparison result, the row hammer management circuit 500 may manage an address and count data of a row having relatively great count data from among a plurality of rows of a bank in a register.

At various opportunities described with reference to FIG. 2A, the memory device 200B may perform the row hammer refresh operation based on the information of the row managed in the register of the register group 600.

Meanwhile, according to implementations, the row hammer management circuit 500 may notify the memory controller 100 of the row hammer risk, based on the count data stored in the register of the register group 600. For example, when at least one of pieces of count data managed in the register(s) of the register group 600 reaches the reference count, the row hammer management circuit 500 may apply the risk signal indicating the risky situation to the alert pin 711. Also, when at least one of the pieces of count data managed in the register(s) of the register group 600 reaches the reference count, the row hammer management circuit 500 may store the flag data indicating the risky situation in the mode register 712. The memory controller 100 may variably control the transmission frequency of the RFM command, as described with reference to FIG. 1, based on the signal applied to the alert pin 711 or the flag data stored in the mode register 712.

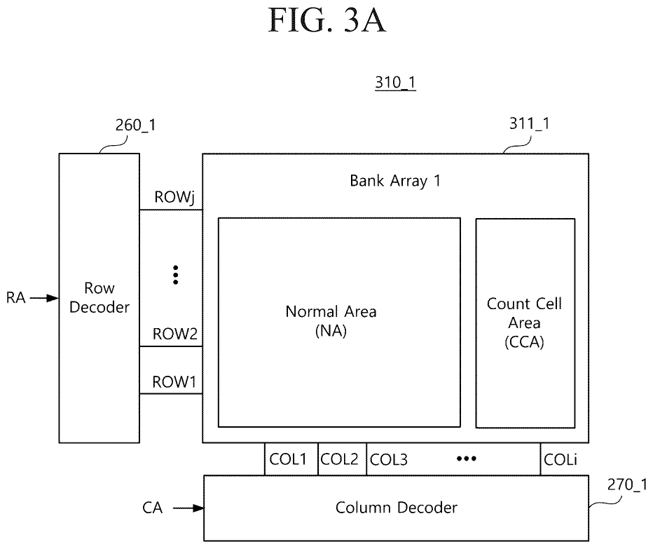

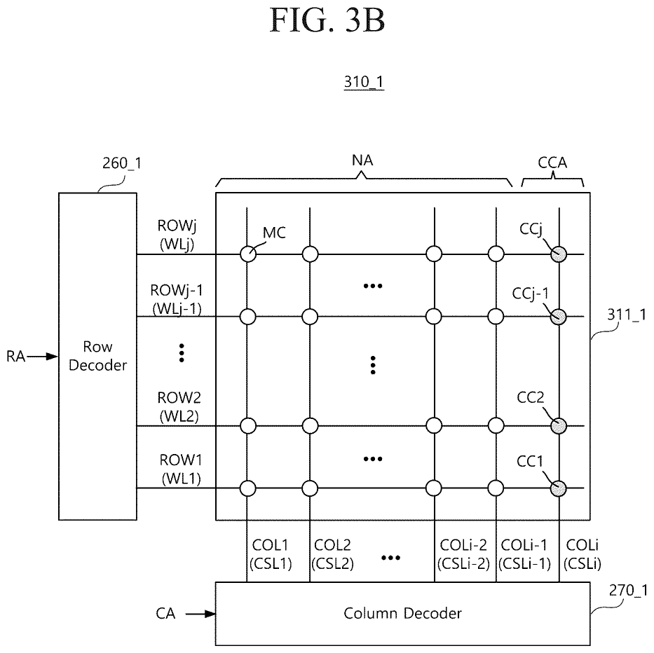

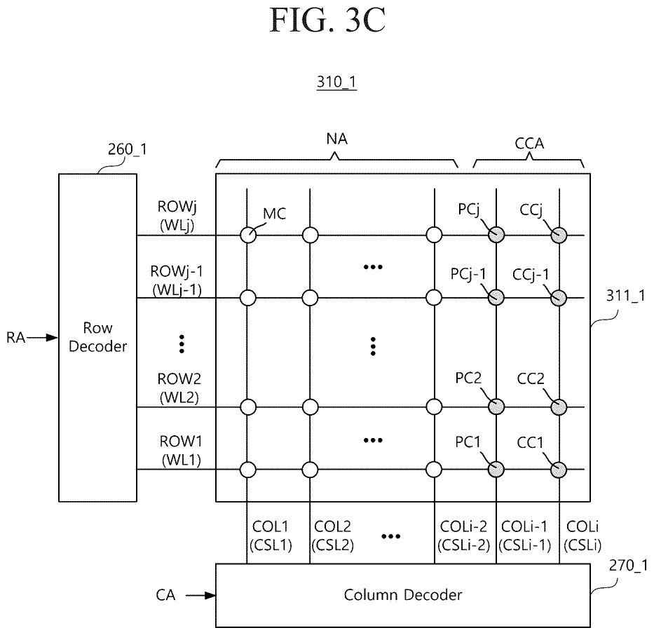

FIG. 3A is a diagram illustrating an example of a bank according to implementations of the present disclosure. The bank 310_1 of FIG. 3A may correspond to the first bank 310_1 of FIGS. 2A and 2B, but the present disclosure is not limited thereto. Referring to FIG. 3A, the first bank 310_1 may include a first bank array 311_1, a row decoder 2601, and a column decoder 270_1.

The first bank array 3111 may include a plurality of memory cells. The first bank array 311_1 may include a normal area NA and the count cell area CCA. The normal area NA may refer to an area of the first bank array 311_1, which is allocated to store user data. Alternatively, the normal area NA may refer to the remaining area of the first bank array 311_1 other than an area allocated to the count cell area CCA. The count cell area CCA may refer to an area of the first bank array 311_1, which is allocated to store count data for each of a plurality of rows ROW1 to ROWj.

The row decoder 260_1 may activate one of the plurality of rows ROW1 to ROWj in response to a row address RA. For example, each of the plurality of rows ROW1 to ROWj may correspond to a word line.

The column decoder 270_1 may activate one of a plurality of columns COL1 to COLi in response to a column address CA. For example, each of the plurality of columns COL1 to COLi may correspond to a column selection line (CSL). However, this is provided as an example. According to implementations, each of the plurality of columns COL1 to COLi may correspond to a bit line.

According to implementations, the count cell area CCA may include count cells for storing the count data for the plurality of rows ROW1 to ROWj. Alternatively, according to implementations, the count cell area CCA may include count cells for storing the count data for the plurality of rows ROW1 to ROWj and parity cells for performing the error correction operation on the count data.

FIG. 3B is a diagram illustrating an example of a bank in which count cells are included in the count cell area CCA. FIG. 3C is a diagram illustrating an example of a bank in which count cells and parity cells are included in the count cell area CCA. The bank 310_1 of FIGS. 3B and 3C may correspond to the first bank 310_1 of FIGS. 2A, 2B, and 3A, but the present disclosure is not limited thereto.

Referring to FIGS. 3B and 3C, the first bank 3101 may include the first bank array 311_1, the row decoder 2601, and the column decoder 270_1.

The first bank array 3111 may include a plurality of memory cells which are electrically connected to a plurality of word lines WL1 to WLj and a plurality of column selection lines CSL1 to CSLi. The plurality of word lines WL1 to WLj may be defined as the plurality of rows ROW1 to ROWj, and the plurality of column selection lines CSL1 to CSLi may be defined as the plurality of columns COL1 to COLi.

A portion of the first bank array 3111 may be allocated to the normal areaNA, and the remaining portion thereof may be allocated to the count cell area CCA.

In this case, according to implementations, as illustrated in FIG. 3B, memory cells corresponding to one of the plurality of columns COL1 to COLi may be allocated to the count cell area CCA. Accordingly, each of a plurality of memory cells CC1 to CCj allocated to the count cell area CCA may store count data for the corresponding row. The memory cells CC1 to CCj storing the count data may be referred to as “count cells”. For example, the first count cell CC1 may store count data for the first row ROW1, the second count cell CC2 may store count data for the second row ROW2, and the j-th count cell CCj may store count data for the j-th row ROWj.

Alternatively, according to implementations, as illustrated in FIG. 3C, memory cells corresponding to at least two of the plurality of columns COL1 to COLi may be allocated to the count cell area CCA. In this case, each of the plurality of memory cells CC1 to CCj corresponding to the i-th column COLi may store count data for the corresponding row. Also, each of a plurality of memory cells PC1 to PCj corresponding to the (i−1)-th column COLi−1 may store parity data for the corresponding count data. The memory cells PC1 to PCj storing the parity data may be referred to as “parity cells”. For example, the first parity cell PC1 may store parity data for the count data stored in the first count cell CC1, the second parity cell PC2 may store parity data for the count data stored in the second count cell CC2, and the j-th parity cell PCj may store parity data for the count data stored in the j-th count cell CCj.

The count data and/or the parity data for each of the plurality of rows ROW1 to ROWj may be managed in the count cell area CCA of the first bank 310_1 through the above method.

Meanwhile, in FIGS. 3B and 3C, the description is given as memory cells corresponding to one of the plurality of columns COL1 to COLi are allocated to count cells or parity cells. However, this is provided as an example. According to implementations, memory cells corresponding to at least two of the plurality of columns COL1 to COLi may be allocated to count cells, and memory cells corresponding to at least two of the remaining columns among the plurality of columns COL1 to COLi may be allocated to parity cells.

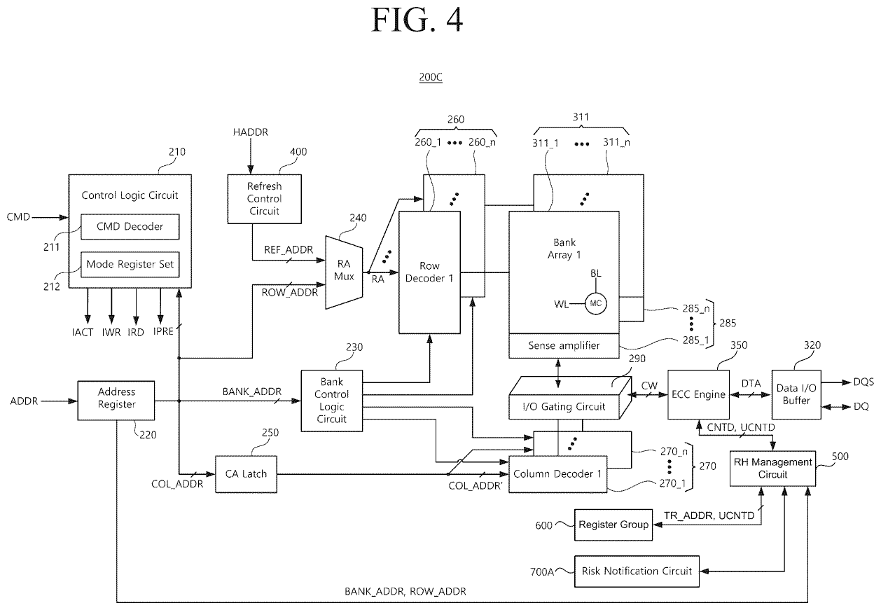

FIG. 4 is a block diagram illustrating a memory device according to implementations of the present disclosure in detail. A memory device 200C of FIG. 4 may be implementations of the memory devices 200, 200A, and 200B of FIGS. 1, 2A, and 2B, but the present disclosure is not limited thereto.

Referring to FIG. 4, the memory device 200C may include a control logic circuit 210, an address register 220, bank control logic circuit 230, a refresh control circuit 400, a row address multiplexer 240, a column address latch 250, a row decoder 260, a column decoder 270, a bank array group 311, a sense amplifier unit 285, an input/output gating circuit 290, an ECC engine 350, a data input/output buffer 320, the row hammer management circuit 500, the register group 600, and the risk notification circuit 700A.

The bank array group 311 may include a plurality of bank arrays 311_1 to 311_n. Each of the plurality of bank arrays 3111 to 311_n may include a plurality of memory cells. For example, each of the plurality of memory cells may be formed at an intersection of a corresponding word line and a corresponding bit line.

The row decoder 260 may include a plurality of sub-row decoders 260_1 to 260_n. Each of the plurality of sub-row decoders 260_1 to 260_n may be connected to the corresponding bank array among the plurality of bank arrays 311_1 to 311_n.

The sense amplifier unit 285 may include a plurality of sense amplifiers 285_1 to 285_n. Each of the plurality of sense amplifiers 285_1 to 285_n may be connected to the corresponding bank array among the plurality of bank arrays 311_1 to 311_n.

The column decoder 270 may include a plurality of sub-column decoders 270_1 to 270_n. Each of the plurality of sub-column decoders 270_1 to 270_n may be connected to the corresponding bank array among the plurality of bank arrays 311_1 to 311_n through the corresponding sense amplifier.

The plurality of bank arrays 311_1 to 311_n, the plurality of sense amplifiers 285_1 to 285_n, the plurality of sub-column decoders 270_1 to 270_n, and the plurality of sub-row decoders 260_1 to 260_n may constitute a plurality of banks. For example, the first bank array 311_1, the first sense amplifier 285_1, the first sub-column decoder 270_1, and the first sub-row decoder 260_1 may constitute the first bank.

The address register 220 may receive an address ADDR including a bank address BANK_ADDR, a row address ROW_ADDR, and a column address COL_ADDR from the memory controller 100. The address register 220 may provide the received bank address BANK_ADDR to the bank control logic circuit 230, may provide the received row address ROW_ADDR to the row address multiplexer 240, and may provide the received column address COL_ADDR to the column address latch 250. Also, the address register 220 may provide the bank address BANK_ADDR and the row address ROW_ADDR to the row hammer management circuit 500.

The bank control logic circuit 230 may generate bank control signals in response to the bank address BANK_ADDR. For example, a sub-row decoder corresponding to the bank address BANK_ADDR from among the plurality of sub-row decoders 260_1 to 260_n may be activated in response to the bank control signals. Also, a sub-column decoder corresponding to the bank address BANK_ADDR from among the plurality of sub-column decoders 270_1 to 270_n may be activated in response to the bank control signals.

The row address multiplexer 240 may receive the row address ROW_ADDR from the address register 220 and may receive a refresh row address REF_ADDR from the refresh control circuit 400. The row address multiplexer 240 may selectively output the row address ROW_ADDR or the refresh row address REF_ADDR as the row address RA. The row address RA output from the row address multiplexer 240 may be applied to each of the plurality of sub-row decoders 260_1 to 260_n.

The refresh control circuit 400 may operate in a normal refresh mode or a row hammer refresh mode. According to implementations, the refresh control circuit 400 may sequentially increase or decrease the refresh row address REF_ADDR in the normal refresh mode. Also, according to implementations, the refresh control circuit 400 may receive a hammer address HADDR in the row hammer refresh mode. Accordingly, the refresh control circuit 400 may output addresses of victim rows adjacent to an aggressor row as the refresh row address REF_ADDR based on the hammer address HADDR.

A sub-row decoder selected by the bank control logic circuit 230 from among the plurality of sub-row decoders 260_1 to 260_n may activate a word line corresponding to the row address RA output from the row address multiplexer 240. For example, the selected sub-row decoder may apply a word line driving voltage to the word line corresponding to a row address.

The column address latch 250 may receive the column address COL_ADDR from the address register 220 and may temporarily store the received column address COL_ADDR. Also, for example, in a burst mode, the column address latch 250 may sequentially increase the received column address COL_ADDR. The column address latch 250 may apply the temporarily stored column address COL_ADDR′ or the sequentially increased column address COL_ADDR′ to each of the plurality of sub-column decoders 270_1 to 270_n.

A sub-column decoder activated by the bank control logic circuit 230 from among the plurality of sub-column decoders 270_1 to 270_n may activate a sense amplifier corresponding to the bank address BANK_ADDR and the column address COL_ADDR through the input/output gating circuit 290.

The input/output gating circuit 290 may include circuits gating input/output data. Also, the input/output gating circuit 290 may include data latches for storing codewords output from the plurality of bank arrays 311_1 to 311_n and write drivers for writing data in the plurality of bank arrays 311_1 to 311_n.

In the read operation, a codeword CW read from a bank array selected from the plurality of bank arrays 311_1 to 311_n may be sensed by a sense amplifier corresponding to the selected bank array and may be stored in the data latches of the input/output gating circuit 290. Also, ECC decoding for the codeword CW stored in the data latches may be performed by the ECC engine 350 so as to be provided to the data input/output buffer 320 as data DTA. The data input/output buffer 320 may generate a data signal DQ based on the data DTA and may provide the data signal DQ to the memory controller 100 together with a strobe signal DQS.

In the write operation, the data DTA to be written in a bank array selected from the plurality of bank arrays 311_1 to 311_n may be received by the data input/output buffer 320 as the data signal DQ. The data input/output buffer 320 may convert the data signal DQ into the data DTA so as to be provided to the ECC engine 350. The ECC engine 350 may generate parity bits (or parity data) based on the data DTA and may provide the input/output gating circuit 290 with the codeword CW including the data DTA and the parity bits. The input/output gating circuit 290 may write the codeword CW in the selected bank array.

In the write operation, the data input/output buffer 320 may convert the data signal DQ into the data DTA so as to be provided to the ECC engine 350. In the read operation, the data input/output buffer 320 may convert the data DTA provided from the ECC engine 350 into the data signal DQ.

In the write operation, the ECC engine 350 may perform ECC encoding for the data DTA. In the read operation, the ECC engine 350 may perform ECC decoding for the codeword CW. Also, the ECC engine 350 may perform ECC encoding and ECC decoding for count data CNTD provided from the row hammer management circuit 500.

The control logic circuit 210 may control an operation of the memory device 200C. For example, the control logic circuit 210 may generate control signals such that the memory device 200C performs the write operation, the read operation, the normal refresh operation, and the row hammer refresh operation. The control logic circuit 210 may include a command decoder 211 which decodes a command CMD received from the memory controller 100 and a mode register (MRS) 212 for setting an operation mode of the memory device 200C.

The command decoder 211 may decode the command CMD to generate internal command signals such as an internal active signal IACT, an internal precharge signal IPRE, an internal read signal IRD, and an internal write signal IWR. Also, the command decoder 211 may generate control signals corresponding to the command CMD by decoding a chip select signal, a command/address signal, etc. Meanwhile, according to implementations, the mode register set 212 may include the mode register 712 in which flag data associated with the row hammer risk is stored and a mode register (e.g., MR4) in which information about a temperature range of the memory device 200C is stored.

The row hammer management circuit 500 may perform various kinds of operations for managing a row hammer phenomenon which occurs in the memory device 200C.

For example, the row hammer management circuit 500 may manage count data for each of a plurality of rows.

According to implementations, the row hammer management circuit 500 may receive the count data CNTD from the ECC engine 350. The row hammer management circuit 500 may modify the count data CNTD and may again provide modified count data UCNTD to the ECC engine 350.

In implementations, when the ACT command for the target row is applied, the count data CNTD stored in the count cell of the target row and the parity data stored in the parity cell of the target row may be provided to the ECC engine 350. The ECC engine 350 may perform the ECC decoding operation on the count data CNTD by using the parity data and may transfer the count data CNTD to the row hammer management circuit 500. The row hammer management circuit 500 may generate the modified count data UCNTD by increasing the count data CNTD as much as “1” or increasing the count data CNTD as much as “k” (k being a natural number of 2 or more) in consideration of the activation time of the target row. The row hammer management circuit 500 may provide the modified count data UCNTD to the ECC engine 350, and the ECC engine 350 may generate the parity data through the ECC encoding operation on the modified count data UCNTD. The modified count data UCNTD and the parity data associated with the modified count data UCNTD may be stored in the count cell and the parity cell of the target row.

According to implementations, the row hammer management circuit 500 may transmit an address TR_ADDR and the modified count data UCNTD of the target row to the register group 600. The row hammer management circuit 500 may selectively update the register group 600 by using the address TR_ADDR and the modified count data UCNTD of the target row.

In implementations, the row hammer management circuit 500 may select a register, which corresponds to a bank to which the target row belongs, from among registers of the register group 600. The row hammer management circuit 500 may compare an address and/or count data managed in the selected register with the address TR_ADDR and/or the modified count data UCNTD of the target row and may update the register based on a comparison result. For example, when at least one of pieces of count data of entries of the register is smaller than the modified count data UCNTD of the target row, the row hammer management circuit 500 may replace the entry of the register corresponding to the smallest count data with the address TR_ADDR of the target row and the modified count data UCNTD. As the memory device 200C manages an address and count data associated with a row having relatively great count data from among a plurality of rows through the register group 600, the memory device 200C may manage the risk of occurrence of the row hammer phenomenon for each row to be equal to or lower than an appropriate level and may effectively prevent the row hammer phenomenon.

Meanwhile, the row hammer management circuit 500 may notify the memory controller 100 of the row hammer risk, based on the count data.

According to implementations, the row hammer management circuit 500 may monitor whether at least one of the pieces of count data stored in a plurality of count cells reaches the reference count. When the count data stored in at least one count cell among the plurality of count cells reaches the reference count, the row hammer management circuit 500 may apply the risk signal indicating the risky situation to the alert pin 711 or may store the flag data indicating the risky situation in the mode register 712.

Alternatively, according to implementations, the row hammer management circuit 500 may monitor whether at least one of the pieces of count data stored in the plurality of count cells reaches the reference count, by using the count data managed in the register of the register group 600. In this case, when at least one of the pieces of count data managed in the registers of the register group 600 reaches the reference count, the row hammer management circuit 500 may apply the risk signal indicating the risky situation to the alert pin 711 or may store the flag data indicating the risky situation in the mode register 712.

Meanwhile, in FIG. 4, the description is given as the memory device 200C includes the ECC engine 350. However, this is provided as an example. According to implementations, the memory device 200C may not include an ECC engine. In this case, the row hammer management circuit 500 may read the count data of the count cell of the target row through the input/output gating circuit 290, may increase the read count data to generate modified count data, and may again write the modified count data in the count cell of the target row through the input/output gating circuit 290.

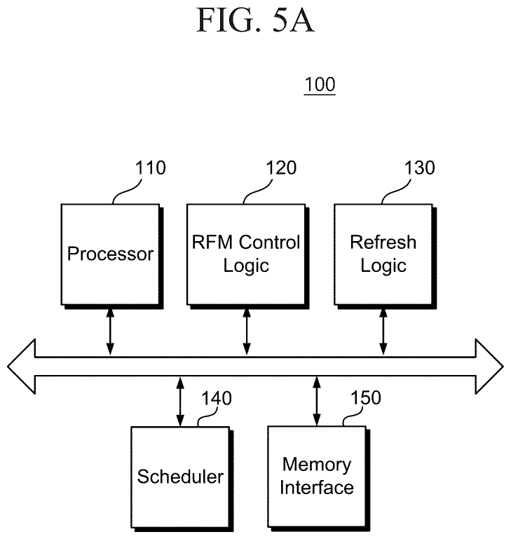

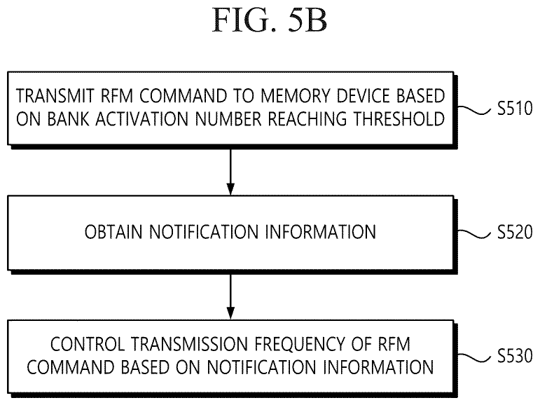

FIG. 5A is a block diagram of a memory controller according to implementations of the present disclosure. The memory controller 100 of FIG. 5A may illustrate implementations of the memory controller 100 of FIG. 1, but the present disclosure is not limited thereto. Referring to FIG. 5A, the memory controller 100 may include a processor 110, RFM control logic 120, refresh logic 130, a scheduler 140, and a memory interface 150 interconnected through a bus.

The processor 110 may control all the operations of the memory controller 100. For example, the processor 110 may individually control the RFM control logic 120, the refresh logic 130, the scheduler 140, and the memory interface 150. The processor 110 may be implemented with a general-purpose processor including one or more processor cores, a dedicated processor, and/or an application processor, but the present disclosure is not limited thereto.

The refresh logic 130 may generate a refresh (REF) command for the normal refresh operation and may transmit the generated REF command to the memory device 200. For example, the memory controller 100 may obtain information about the refresh interval time tREFI from the memory device 200. Accordingly, the refresh logic 130 may generate the REF command every period corresponding to the refresh interval time tREFI and may transmit the REF command to the memory device 200. However, the present disclosure is not limited thereto. According to an embodiment, the memory device 200 may perform the normal refresh operation based on the received REF command. Also, according to an embodiment, the memory device 200 may perform the normal refresh operation and the row hammer refresh operation based on the received REF command.

The scheduler 140 may schedule a sequence of commands generated in the memory controller 100 and may manage the transmission of the commands. The memory interface 150 may perform interfacing with the memory device 200.

The RFM control logic 120 may generate the refresh management (RFM) command for the row hammer refresh operation and may transmit the generated RFM command to the memory device 200.

In particular, the RFM control logic 120 may perform various operations of the memory controller 100 associated with the above transmission of the RFM command. For example, the RFM control logic 120 may count the number of times of bank activation of a bank included in the memory device 200 and may transmit the RFM command to the memory device 200 based on whether the counted number of times of bank activation reaches the BAT.

In implementations, the RFM control logic 120 may variably control the transmission frequency of the RFM command depending on information associated with the situation of the memory device 200. For example, based on the row hammer risk of the memory device 200 obtained through the notification circuit 700 or temperature information including a temperature range of the memory device 200, the RFM control logic 120 may selectively control whether to transmit the RFM command or may adjust the BAT. Also, the RFM control logic 120 may transmit the RFM command further in consideration of the activation time of the bank included in the memory device 200.

According to the above implementations, the transmission frequency of the RFM command may be variably controlled in consideration of various situations of the memory device 200, such as a row hammer risk, a refresh interval time according to a temperature range, and a PGE phenomenon of a memory cell. Accordingly, the efficiency of bandwidth of a memory system or the performance of the memory system may be improved.

FIG. 5B is a flowchart illustrating an operating method of a memory controller according to implementations of the present disclosure.

Referring to FIG. 5B, in operation S510, the memory controller 100 may transmit the RFM command to the memory device 200, based on that number of times of bank activation of a bank included in the memory device 200 reaches the BAT. For example, the memory controller 100 may count the number of times of bank activation whenever the ACT command is transmitted to the memory device 200 and may transmit the RFM command to the memory device 200 when the counted number of times of bank activation reaches the BAT.

In operation S520, the memory controller 100 may obtain notification through the notification circuit 700 of the memory device 200. In implementations, the notification may include at least one of information about row hammer risks of rows included in the bank of the memory device 200 or temperature information including a temperature range of the memory device 200.

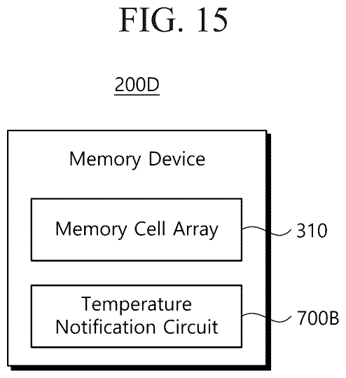

In detail, the notification circuit 700 may include the risk notification circuit 700A and/or a temperature notification circuit 700B (refer to FIG. 15).

The risk notification circuit 700A may include at least one of the alert pin 711 or the mode register 712. A signal associated with the row hammer risk may be applied to the alert pin 711, and the mode register 712 may store flag data associated with the row hammer risk. Accordingly, the memory controller 100 may receive the signal applied to the alert pin 711 and may obtain the row hammer risk of the memory device 200. Also, the memory controller 100 may obtain the row hammer risk of the memory device 200 by reading the flag data stored in the mode register 712 through the mode register read operation.

The temperature notification circuit 700B may notify the memory controller 100 of information about a temperature of the memory device 200. For example, the temperature notification circuit 700B may be implemented with a mode register storing temperature information including a temperature range of the memory device 200, but the present disclosure is not limited thereto. When the temperature notification circuit 700B is implemented with the mode register, the memory controller 100 may obtain the temperature information of the memory device 200 through the mode register read operation on the corresponding register.

In operation S530, the memory controller 100 may variably control the transmission frequency of the RFM command based on the obtained notification. In detail, based on the notification, the memory controller 100 may selectively transmit the RFM command or may adjust the BAT.

According to implementations, the memory controller 100 may selectively transmit the RFM command based on the row hammer risk obtained through the risk notification circuit 700A. As described above, when count data stored in at least one of a plurality of count cells of the memory device 200 reaches the reference count, the risk signal may be applied to the alert pin 711, and the flag data may be stored in the mode register 712. Accordingly, before the risk signal is received through the alert pin 711 or the flag data is read from the mode register 712, the memory controller 100 may determine that the row hammer risk of the memory device 200 is low. In this case, even though the number of times of bank activation reaches the BAT, the memory controller 100 may not transmit the RFM command. In contrast, when the risk signal is received through the alert pin 711 or the flag data read from the mode register 712 indicates the risky situation, the row hammer risk of the memory device 200 may be determined as reaching the risk level. In this case, whenever the number of times of bank activation reaches the BAT, the memory controller 100 may transmit the RFM command to the memory device 200.

According to implementations, the memory controller 100 may adjust the BAT based on the row hammer risk obtained through the risk notification circuit 700A. For example, in a situation where the row hammer risk is low, whenever the number of times of bank activation reaches the BAT1, the memory controller 100 may transmit the RFM command to the memory device 200. In contrast, in a situation where the row hammer risk reaches the risk level (e.g., risk is high), whenever the number of times of bank activation reaches the BAT2, the memory controller 100 may transmit the RFM command to the memory device 200. As described above, because the BAT2 is lower in value than the BAT1, the transmission frequency of the RFM command corresponding to the case of operating based on the BAT1 may be relatively low compared to the transmission frequency of the RFM command corresponding to the case of operating based on the BAT2.

According to implementations, the memory controller 100 may adjust the BAT based on the temperature information of the memory device 200 obtained through the temperature notification circuit 700B. For example, in a situation where the temperature range of the memory device 200 is a first temperature range being relatively low, whenever the number of times of bank activation reaches the BAT3, the memory controller 100 may transmit the RFM command to the memory device 200. In contrast, in a situation where the temperature range of the memory device 200 is a second temperature range being relatively high, whenever the number of times of bank activation reaches the BAT4, the memory controller 100 may transmit the RFM command to the memory device 200. As described above, because the BAT3 is lower in value than the BAT4, the transmission frequency of the RFM command corresponding to the case of operating based on the BAT4 may be relatively low compared to the transmission frequency of the RFM command corresponding to the case of operating based on the BAT3.

Meanwhile, the memory controller 100 may transmit the RFM command further in consideration of an activation time of a bank included in the memory device 200.

According to implementations, when any one of a threshold condition (i.e., the BAT) associated with the number of times of bank activation and a threshold condition (i.e., the BATT) associated with the bank activation time is satisfied, the memory controller 100 may transmit the RFM command to the memory device 200. In this case, even though the number of times of bank activation does not reach the BAT, when the bank activation time reaches the BATT, the RFM command may be transmitted.

According to implementations, the memory controller 100 may count the number of times of bank activation in consideration of the bank activation time. In implementations, when the bank activation time is equal to or smaller than the reference time, the memory controller 100 may increase the number of times of bank activation as much as “1”. Also, when the bank activation time exceeds the reference time, the memory controller 100 may increase the number of times of bank activation as much as “2”.

According to the above implementations, the transmission frequency of the RFM command may be variably controlled in consideration of various situations of the memory device 200, such as a row hammer risk, a refresh interval time according to a temperature range, and a PGE phenomenon of a memory cell. Accordingly, the efficiency of bandwidth of a memory system or the performance of the memory system may be improved.

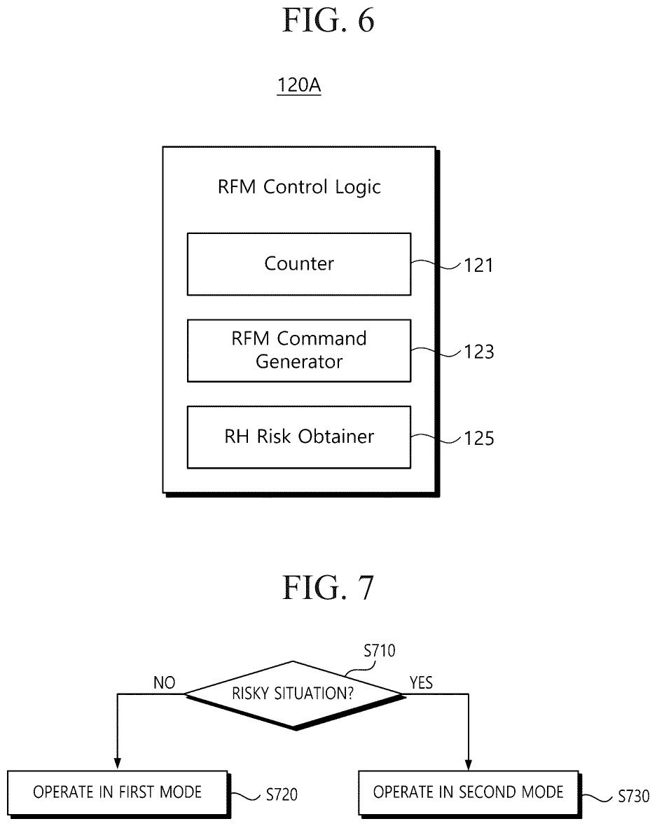

FIG. 6 is a block diagram illustrating a configuration of RFM control logic according to implementations of the present disclosure. Referring to FIG. 6, the RFM control logic 120 may include a counter 121, an RFM command generator 123, and a row hammer risk obtainer 125.

The counter 121 may count the number of times of bank activation. According to implementations, the counter 121 may count the number of times of bank activation based on the ACT command transmitted to the memory device 200. For example, the counter 121 may increase the number of times of bank activation as much as “1” whenever the ACT command is transmitted to the memory device 200. Below, for convenience, the description will be given as the number of times of bank activation is counted based on the ACT command, but implementations are not limited thereto. For example, the counter 121 may count the number of times of bank activation as much as “1” based on the PRE command transmitted to the memory device 200.

Meanwhile, according to implementations, the counter 121 may be provided for each bank of the memory device 200. The counter 121 corresponding to each bank may count the number of times of bank activation of the corresponding bank.

The row hammer risk obtainer 125 may obtain the row hammer risk of the memory device 200 through the risk notification circuit 700A. For example, the row hammer risk obtainer 125 may receive the signal applied to the alert pin 711 and may obtain the row hammer risk of the memory device 200. Also, the row hammer risk obtainer 125 may obtain the row hammer risk of the memory device 200 by reading the flag data stored in the mode register 712 through the mode register read operation.

The RFM command generator 123 may generate the RFM command based on the number of times of bank activation counted by the counter 121 and the row hammer risk of the memory device 200 obtained through the row hammer risk obtainer 125 and may transmit the generated RFM command to the memory device 200.

According to implementations, the RFM command generator 123 may operate in the first mode or the second mode, based on the row hammer risk. In the first mode, even though the number of times of bank activation reaches the BAT, the RFM command generator 123 may not transmit the RFM command; in the second mode, when the number of times of bank activation reaches the BAT, the RFM command generator 123 may transmit the RFM command. In other words, when the number of times of bank activation reaches the BAT, the RFM command may be selectively transmitted based on the row hammer risk.

Also, according to implementations, the RFM command generator 123 may operate in the third mode or the fourth mode, based on the row hammer risk. In the third mode, when the number of times of bank activation reaches the BAT1, the RFM command generator 123 may transmit the RFM command; in the fourth mode, when the number of times of bank activation reaches the BAT2, the RFM command generator 123 may transmit the RFM command. Accordingly, the BAT value may be appropriately adjusted based on the row hammer risk.

Below, various implementations in which the RFM command is selectively transmitted based on the row hammer risk will be described with reference to FIGS. 7 to 10.

FIG. 7 is a flowchart illustrating an operating method of a memory controller according to implementations of the present disclosure. Referring to FIG. 7, in operation S710, the memory controller 100 may determine whether the memory device 200 is in the risky situation in association with the row hammer. For example, the memory controller 100 may determine whether the memory device 200 is in a risky situation, based on the row hammer risk of the memory device 200 obtained through the risk notification circuit 700A.

In detail, the row hammer risk may indicate whether count data stored in at least one of a plurality of count cells respectively corresponding to a plurality of rows included in a bank of the memory device 200 reaches the reference count. When the count data reach the reference count, the memory device 200 may apply the risk signal indicating the risky situation to the alert pin 711 or may store the flag data indicating the risky situation in the mode register 712. In this case, according to implementations, the case where the count data reach the reference count may include the case where the count data exceed the reference count, in addition to the case where the count data coincide with the reference count.

Accordingly, when the risk signal is received through the alert pin 711 or the flag data read from the mode register 712 indicates the risky situation, the memory controller 100 may determine that the memory device 200 is in the risky situation in association with the row hammer. Also, when the risk signal is not received through the alert pin 711 and the flag data read from the mode register 712 does not indicate the risky situation, the memory controller 100 may determine that the memory device 200 is not in the risky situation in association with the row hammer.

When the memory device 200 is not in the risky situation in association with the row hammer (No in operation S710), the memory controller 100 may perform operation S720. In operation S720, the memory controller 100 may operate in the first mode. In the first mode, even though the number of times of bank activation reaches the BAT, the memory controller 100 may not transmit the RFM command to the memory device 200.

Meanwhile, when the memory device 200 is in the risky situation in association with the row hammer (Yes in operation S710), the memory controller 100 may perform operation S730. In operation S730, the memory controller 100 may operate in the second mode. In the second mode, when the number of times of bank activation reaches the BAT, the memory controller 100 may transmit the RFM command to the memory device 200.

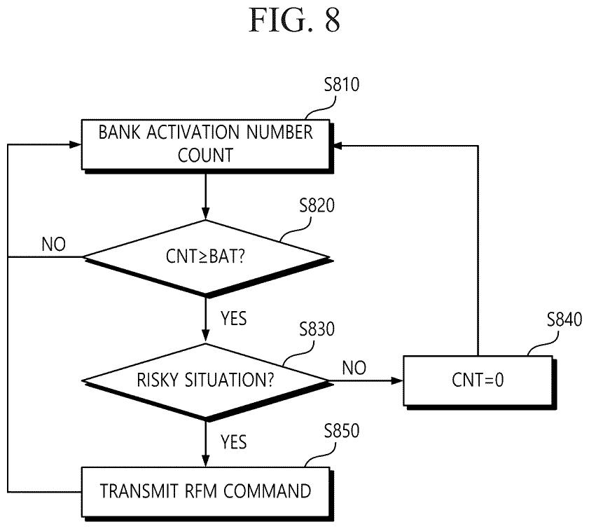

FIG. 8 is a flowchart illustrating an operating method of a memory controller according to implementations of the present disclosure.

Referring to FIG. 8, in operation S810, the memory controller 100 may count the number of times of bank activation. For example, whenever the ACT command for a specific bank of the memory device 200 is transmitted, the memory controller 100 may increase the number of times of bank activation as much as “1”.

In operation S820, the memory controller 100 may determine whether the counted number of times of bank activation, denoted as CNT, reaches the BAT. In this case, as described above, the case where the counted number of times of bank activation, denoted as CNT, reaches the BAT may include the case where the counted number of times of bank activation, denoted as CNT, is greater in value than the BAT, in addition to the case where the counted number of times of bank activation, denoted as CNT, coincides with the BAT.

Accordingly, according to implementations, the memory controller 100 may determine whether the counted number of times of bank activation, denoted as CNT, reaches the BAT, by determining whether the counted number of times of bank activation, denoted as CNT, is equal to or greater than the BAT.

When the counted number of times of bank activation, denoted as CNT, is smaller than the BAT, that is, when the counted number of times of bank activation, denoted as CNT, does not reach the BAT (No in operation S820), the memory controller 100 may again perform operation S810. When the counted number of times of bank activation, denoted as CNT, is equal to or greater than the BAT, that is, when the counted number of times of bank activation, denoted as CNT, reaches the BAT (Yes in operation S820), the memory controller 100 may perform operation S830.

In operation S830, the memory controller 100 may determine whether the memory device 200 is in the risky situation in association with the row hammer. For example, the memory controller 100 may determine whether the memory device 200 is in the risky situation, based on the row hammer risk obtained through the risk notification circuit 700A. According to implementations, the memory controller 100 may determine whether the memory device 200 is in the risky situation, through the mode register read operation on the mode register 712.

For example, when the flag data read from the mode register 712 is the risk flag, the memory controller 100 may determine that the memory device 200 is in the risky situation. Also, when the flag data read from the mode register 712 is not the risk flag, the memory controller 100 may determine that the memory device 200 is not in the risky situation.

When the memory device 200 is not in the risky situation (No in operation S830), the memory controller 100 may perform operation S840. In operation S840, the memory controller 100 may reset the number of times of bank activation, denoted as CNT. Accordingly, the memory controller 100 may again perform operation S810.

Meanwhile, when the memory device 200 is in the risky situation (Yes in operation S830), the memory controller 100 may perform operation S850. In operation S850, the memory controller 100 may transmit the RFM command to the memory device 200. In this case, the memory controller 100 may reset the number of times of bank activation, denoted as CNT. Accordingly, the memory controller 100 may again perform operation S810.

That is, referring again to FIG. 8, while operating in the first mode, the memory controller 100 may operate in order of operation S810, operation S820, operation S830, and operation S840. Also, while operating in the second mode, the memory controller 100 may operate in order of operation S810, operation S820, operation S830, and operation S850. In this case, whenever the number of times of bank activation, denoted as CNT, reaches the BAT (Yes in operation S820), the memory controller 100 may perform the mode register read operation and may operate in the first mode or the second mode depending on whether the flag data read from the mode register 712 is the risk flag.

Meanwhile, according to implementations, while operating in the first mode, the memory controller 100 may perform the mode register read operation whenever the number of times of bank activation, denoted as CNT, reaches the BAT (Yes in operation S820). However, when the flag data is obtained from the mode register 712 while operating in the first mode (Yes in operation S830), unlike the example illustrated in FIG. 8, the memory controller 100 may operate in the second mode without performing the mode register read operation until the RFM command is transmitted as much as the given number of times. In this case, the memory controller 100 may perform the mode register read operation after the RFM command is transmitted as much as the given number of times.

The reason is that as the memory device 200 escapes from the risky situation, a situation where the memory controller 100 under the operation in the second mode changes the mode into the first mode is not a situation where the memory controller 100 should urgently change the mode.

Accordingly, the memory controller 100 may quickly detect the case where there occurs the risky situation associated with the row hammer while operating in the first mode and may immediately operate in the second mode. Also, when the memory controller 100 enters the second mode, the memory controller 100 may not perform the mode register read operation until the RFM command is transmitted as much as the given number of times. Accordingly, resource consumption necessary for the mode register read operation may be reduced.

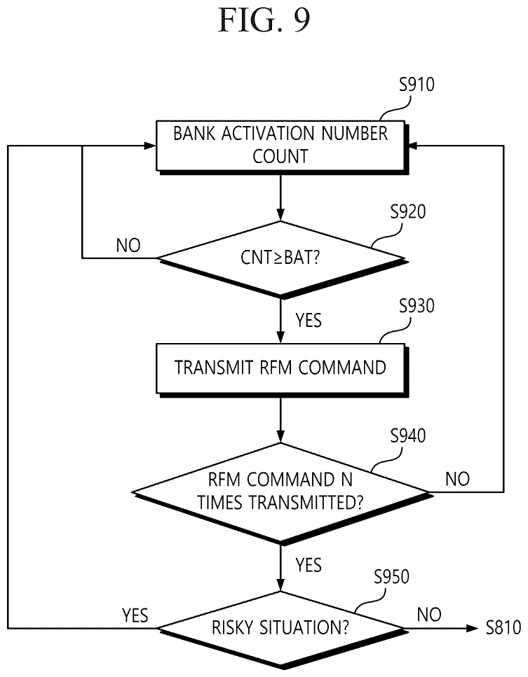

Below, implementations in which the memory controller 100 performs the mode register read operation on the mode register 712 after operating in the second mode until the RFM command is transmitted as much as the given number of times will be described with reference to FIG. 9.

FIG. 9 is a flowchart illustrating an operating method of a memory controller according to implementations of the present disclosure.

Referring to FIG. 9, in operation S910, the memory controller 100 may count the number of times of bank activation.

In operation S920, the memory controller 100 may determine whether the counted number of times of bank activation, denoted as CNT, reaches the BAT.

When the counted number of times of bank activation, denoted as CNT, is smaller than the BAT, that is, when the counted number of times of bank activation, denoted as CNT, does not reach the BAT (No in operation S920), the memory controller 100 may again perform operation S910. When the counted number of times of bank activation, denoted as CNT, is equal to or greater than the BAT, that is, when the counted number of times of bank activation, denoted as CNT, reaches the BAT (Yes in operation S920), the memory controller 100 may perform operation S930.

In operation S930, the memory controller 100 may transmit the RFM command to the memory device 200. In this case, the memory controller 100 may reset the number of times of bank activation, denoted as CNT.

In operation S940, the memory controller 100 may determine whether the RFM command is transmitted as much as the given number of times “N”. According to implementations, the given number of times “N” may be set to one of the positive integers.

When the RFM command is not transmitted as much as the given number of times “N” (No in operation S940), the memory controller 100 may again perform operation S910. When the RFM command is transmitted as much as the given number of times “N” (Yes in operation S940), the memory controller 100 may perform operation S950.

Referring to operation S910 to operation S940 described above, until the RFM command is transmitted as much as the given number of times “N”, the memory controller 100 may operate in the second mode without performing the mode register read operation on the mode register 712.

In operation S950, the memory controller 100 may determine whether the memory device 200 is in the risky situation in association with the row hammer. For example, the memory controller 100 may determine whether the memory device 200 is in the risky situation, based on the row hammer risk obtained through the risk notification circuit 700A. According to implementations, the memory controller 100 may determine whether the memory device 200 is in the risky situation, through the mode register read operation on the mode register 712.

When the memory device 200 is not in the risky situation (No in operation S950), the memory controller 100 may perform operation S810 of FIG. 8.

When the memory device 200 is in the risky situation (Yes in operation S950), the memory controller 100 may perform operation S910. In this case, until the RFM command is transmitted as much as the given number of times “N”, the memory controller 100 may operate in the second mode without performing the mode register read operation.

Meanwhile, the case where the memory controller 100 performs the mode register read operation on the mode register 712 in both operation S930 and operation S950 to determine whether the memory device 200 is in the risky situation is described above as an example. In this case, for example, the memory controller 100 under the operation in the first mode may operate in the second mode when the flag data read from the mode register 712 indicates the risky situation (Yes in operation S830). According to implementations, in this case, as described with reference to FIG. 9, the memory controller 100 may operate in the second mode until the RFM command is transmitted as much as the given number of times “N” and may then perform the mode register read operation on the mode register 712. Accordingly, when the flag data is read and does not indicate the risky situation (No in operation S950), the memory controller 100 may again operate in the first mode.

However, implementations are not limited thereto. For example, in operation S830, the memory controller 100 may determine whether the risky situation of the memory device 200 occurs, based on the signal received through the alert pin 711; in operation S950, the memory controller 100 may determine whether the risky situation of the memory device 200 occurs, based on the mode register read operation on the mode register 712. In this case, for example, the memory controller 100 under the operation in the first mode may operate in the second mode when the risk signal is applied to the alert pin 711 (Yes in operation S830). According to implementations, in this case, as described with reference to FIG. 9, the memory controller 100 may operate in the second mode until the RFM command is transmitted as much as the given number of times “N” and may then perform the mode register read operation on the mode register 712. When the flag data obtained through the mode register read operation does not indicate the risky situation (No in operation S950), the memory controller 100 may again operate in the first mode.

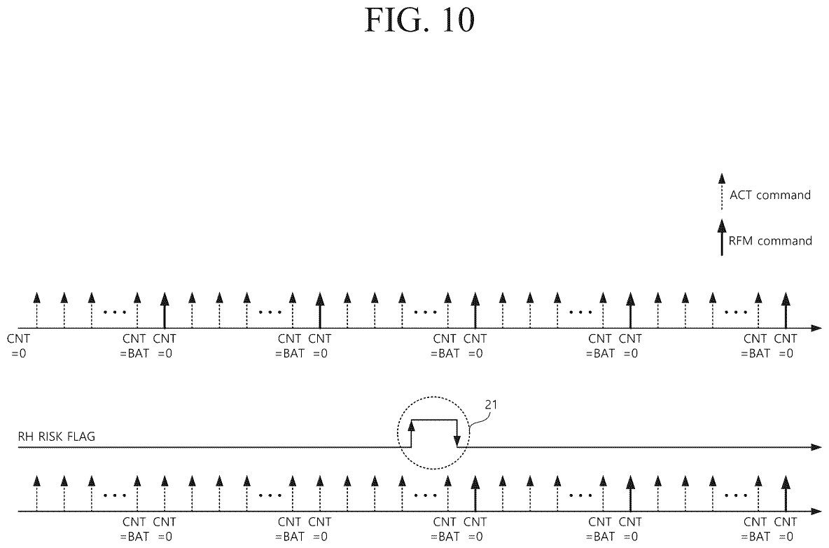

FIG. 10 is a diagram for describing an operation in which an RFM command is selectively transmitted, according to implementations of the present disclosure. The top drawing of FIG. 10 shows an example in which the RFM command is transmitted without consideration of the row hammer risk, and the bottom drawing of FIG. 10 shows an example in which the RFM command is selectively transmitted depending on the row hammer risk.

In the bottom drawing of FIG. 10, a row hammer flag data RH RISK FLAG may refer to a signal indicating the row hammer risk of the memory device 200. For example, the row hammer flag data RH RISK FLAG may refer to a flag data signal of the row hammer risk read from the mode register 712 (or a signal of the row hammer risk applied to the alert pin 711). Reference numeral 21 may refer to a flag data signal indicating the risky situation read from the mode register 712 (or the risk signal applied to the alert pin 711).

Referring to the top drawing of FIG. 10, the memory controller 100 may transmit the RFM command whenever the number of times of bank activation, denoted as CNT reaches the BAT.

Referring to the bottom drawing of FIG. 10, even though the number of times of bank activation, denoted as CNT, reaches the BAT, the memory controller 100 may selectively transmit the RFM command depending on the row hammer flag data RH RISK FLAG.

According to implementations, when the memory device 200 is not in the risky situation associated with the row hammer risk, the memory controller 100 may operate in the first mode. For example, even though the number of times of bank activation, denoted as CNT, reaches the BAT, the memory controller 100 may not transmit the RFM command until the flag data signal (or risk signal) 21 is obtained.

Meanwhile, when the flag data signal (or risk signal) 21 is obtained, the memory controller 100 under the operation in the first mode may operate in the second mode. In the bottom drawing of FIG. 10, a drawing part after the flag data signal (or risk signal) 21 is applied shows the operation in the second mode in which the RFM command is transmitted whenever the number of times of bank activation, denoted as CNT, reaches the BAT.

In this case, according to implementations, the memory controller 100 may operate in the second mode until the RFM command is transmitted as much as the given number of times. In implementations, until the number of times of transmission of the RFM command reaches the given number of times, the memory controller 100 may not perform the mode register read operation on the mode register 712.

When the RFM command is transmitted as much as the given number of times while operating in the second mode, the memory controller 100 may perform the mode register read operation on the mode register 712. When the flag data read from the mode register 712 is not the flag data indicating the risky situation, the memory controller 100 may operate in the first mode. When the read flag is the flag data indicating the risky situation, the memory controller 100 may again operate in the second mode until the RFM command is transmitted as much as the given number of times.

Alternatively, according to implementations, when the RFM command is transmitted as much as the given number of times while operating in the second mode, the memory controller 100 may check the signal applied to the alert pin 711 and may determine whether to operate in the first mode based on the checked signal. For example, when the signal applied to the alert pin 711 is checked as being not the risk signal at a point in time when the RFM command is completely transmitted as much as the given number of times, the memory controller 100 may operate in the first mode. When the signal applied to the alert pin 711 is checked as being the risk signal at a point in time when the RFM command is completely transmitted as much as the given number of times, the memory controller 100 may operate in the second mode until the RFM command is transmitted as much as the given number of times.

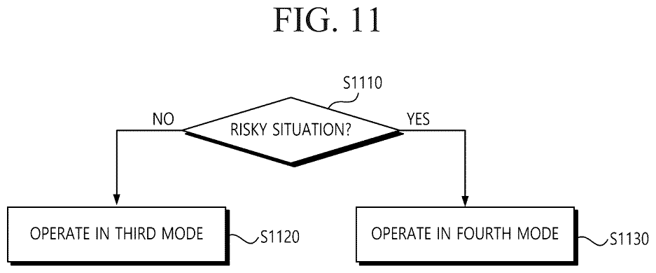

Below, various implementations in which the BAT value is changed based on the row hammer risk will be described with reference to FIGS. 11 to 14. In describing FIGS. 11 to 14, the description which is given above will be omitted or simplified.

FIG. 11 is a flowchart illustrating an operating method of a memory controller according to implementations of the present disclosure. Referring to FIG. 11, in operation S1110, the memory controller 100 may determine whether the memory device 200 is in the risky situation in association with the row hammer.

When the memory device 200 is not in the risky situation in association with the row hammer (No in operation S1110), the memory controller 100 may perform operation S1120. In operation S1120, the memory controller 100 may operate in the third mode. In the third mode, when the number of times of bank activation reaches the BAT1, the memory controller 100 may transmit the RFM command to the memory device 200.

Meanwhile, when the memory device 200 is in the risky situation in association with the row hammer (Yes in operation S1110), the memory controller 100 may perform operation S1130. In operation S1130, the memory controller 100 may operate in the fourth mode. In the fourth mode, when the number of times of bank activation reaches the BAT2, the memory controller 100 may transmit the RFM command to the memory device 200. According to implementations, the BAT2 may be smaller in value than the BAT1. That is, the transmission frequency of the RFM command in the fourth mode may be higher than the transmission frequency of the RFM command in the third mode.

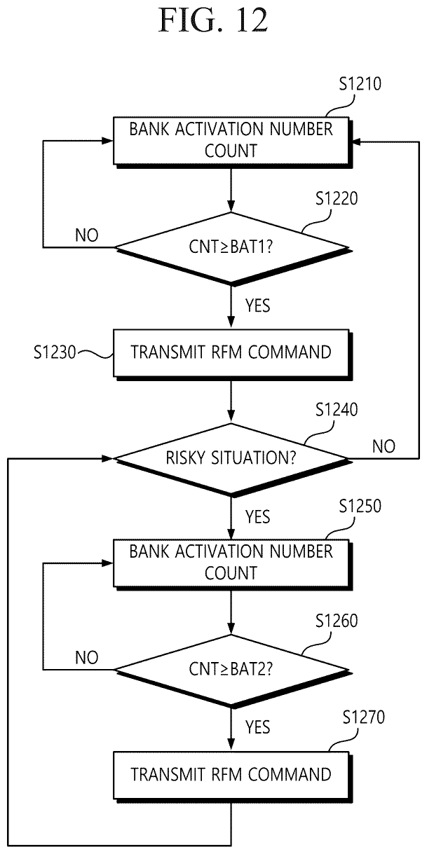

FIG. 12 is a flowchart illustrating an operating method of a memory controller according to implementations of the present disclosure.

Referring to FIG. 12, in operation S1210, the memory controller 100 may count the number of times of bank activation.

In operation S1220, the memory controller 100 may determine whether the counted number of times of bank activation, denoted as CNT, reaches the BAT1. In implementations, the case where the counted number of times of bank activation, denoted as CNT, reaches the BAT1 may include the case where the counted number of times of bank activation, denoted as CNT, is greater in value than the BAT1, in addition to the case where the counted number of times of bank activation, denoted as CNT, coincides with the BAT1.

According to implementations, thus, the memory controller 100 may determine whether the counted number of times of bank activation, denoted as CNT, reaches the BAT1, by determining whether the counted number of times of bank activation, denoted as CNT, is equal to or greater than the BAT1.

When the counted number of times of bank activation, denoted as CNT, is smaller than the BAT1, that is, when the counted number of times of bank activation, denoted as CNT, does not reach the BAT1 (No in operation S1220), the memory controller 100 may again perform operation S1210. When the counted number of times of bank activation, denoted as CNT, is equal to or greater than the BAT1, that is, when the counted number of times of bank activation, denoted as CNT, reaches the BAT1 (Yes in operation S1220), the memory controller 100 may perform operation S1230.

In operation S1230, the memory controller 100 may transmit the RFM command to the memory device 200. In this case, the memory controller 100 may reset the number of times of bank activation, denoted as CNT.

In operation S1240, the memory controller 100 may determine whether the memory device 200 is in the risky situation in association with the row hammer. For example, when the flag read from the mode register 712 indicates the risky situation, the memory controller 100 may determine that the memory device 200 is in the risky situation. Also, when the flag read from the mode register 712 does not indicate the risky situation, the memory controller 100 may determine that the memory device 200 is not in the risky situation.

When the memory device 200 is not in the risky situation (No in operation S1240), the memory controller 100 may again perform operation S1210.

Meanwhile, when the memory device 200 is in the risky situation (Yes in operation S1240), the memory controller 100 may perform operation S1250. In operation S1250, the memory controller 100 may count the number of times of bank activation.

In operation S1260, the memory controller 100 may determine whether the counted number of times of bank activation, denoted as CNT, reaches the BAT2. In implementations, the BAT2 may be smaller in value than the BAT1. Meanwhile, as described above, the case where the counted number of times of bank activation, denoted as CNT, reaches the BAT2 may include the case where the counted number of times of bank activation, denoted as CNT, is greater in value than the BAT2, in addition to the case where the counted number of times of bank activation, denoted as CNT, coincides with the BAT2.

According to implementations, thus, the memory controller 100 may determine whether the counted number of times of bank activation, denoted as CNT, reaches the BAT2, by determining whether the counted number of times of bank activation, denoted as CNT, is equal to or greater than the BAT2.

When the counted number of times of bank activation, denoted as CNT, is smaller than the BAT2, that is, when the counted number of times of bank activation, denoted as CNT, does not reach the BAT2 (No in operation S1260), the memory controller 100 may again perform operation S1250. When the counted number of times of bank activation, denoted as CNT, is equal to or greater than the BAT2, that is, when the counted number of times of bank activation, denoted as CNT, reaches the BAT2 (Yes in operation S1260), the memory controller 100 may perform operation S1270.

In operation S1270, the memory controller 100 may transmit the RFM command to the memory device 200. In this case, the memory controller 100 may reset the number of times of bank activation, denoted as CNT. Accordingly, the memory controller 100 may again perform operation S1240.

That is, referring again to FIG. 12, while operating in the third mode, the memory controller 100 may operate in order of operation S1210, operation S1220, operation S1230, and operation S1240. Also, while operating in the fourth mode, the memory controller 100 may operate in order of operation S1250, operation S1260, operation S1270, and operation S1240. In this case, whenever the RFM command is transmitted in response to that the number of times of bank activation, denoted as CNT, reaches the BAT1 or BAT2 (S1230 or S1270), the memory controller 100 may perform the mode register read operation and may operate in the third mode or the fourth mode depending on whether the flag read from the mode register 712 is the flag data.

Meanwhile, according to implementations, while operating in the third mode, the memory controller 100 may perform the mode register read operation whenever the number of times of bank activation, denoted as CNT, reaches the BAT1 (Yes in operation S1220). However, when the flag data indicating the risky situation is obtained from the mode register 712 while operating in the third mode (Yes in operation S1240), unlike the example illustrated in FIG. 12, the memory controller 100 may operate in the fourth mode without performing the mode register read operation until the RFM command is transmitted as much as the given number of times. In this case, the memory controller 100 may perform the mode register read operation after the RFM command is transmitted as much as the given number of times.

The reason is that as the memory device 200 escapes from the risky situation, a situation where the memory controller 100 under the operation in the fourth mode changes the mode into the third mode is not a situation where the memory controller 100 should urgently change the mode.

Accordingly, the memory controller 100 may quickly detect the case where there occurs the risky situation associated with the row hammer while operating in the third mode and may immediately operate in the fourth mode. Also, when the memory controller 100 enters the fourth mode, the memory controller 100 may not perform the mode register read operation until the RFM command is transmitted as much as the given number of times. Accordingly, resource consumption necessary for the mode register read operation may be reduced.

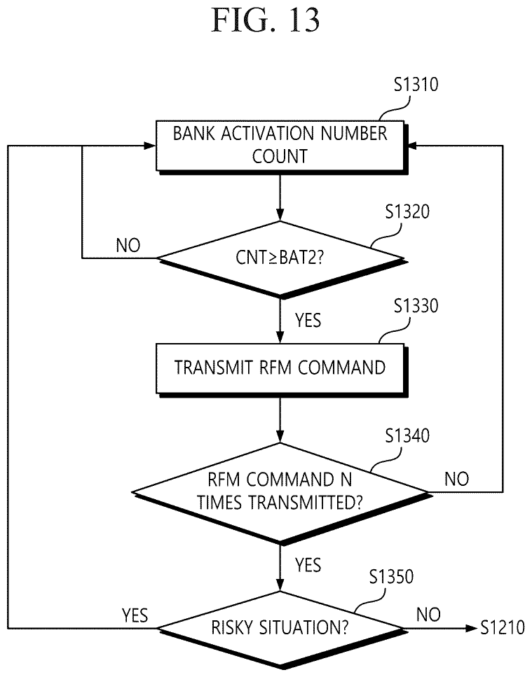

Below, implementations in which the memory controller 100 performs the mode register read operation on the mode register 712 after operating in the fourth mode until the RFM command is transmitted as much as the given number of times will be described with reference to FIG. 13. According to implementations, operations in the fourth mode illustrated in FIG. 13 may correspond to operations in the fourth mode illustrated in FIG. 12, and operation S1310, operation S1320, operation S1330, and operation S1350 may respectively correspond to operation S1250, operation S1260, operation S1270, and operation S1240.

FIG. 13 is a flowchart illustrating an operating method of a memory controller according to implementations of the present disclosure.

Referring to FIG. 13, in operation S1310, the memory controller 100 may count the number of times of bank activation.

In operation S1320, the memory controller 100 may determine whether the counted number of times of bank activation, denoted as CNT, reaches the BAT2.

When the counted number of times of bank activation, denoted as CNT, is smaller than the BAT2, that is, when the counted number of times of bank activation, denoted as CNT, does not reach the BAT2 (No in operation S1320), the memory controller 100 may again perform operation S1310. When the counted number of times of bank activation, denoted as CNT, is equal to or greater than the BAT2, that is, when the counted number of times of bank activation, denoted as CNT, reaches the BAT2 (Yes in operation S1320), the memory controller 100 may perform operation S1330.

In operation S1330, the memory controller 100 may transmit the RFM command to the memory device 200. In this case, the memory controller 100 may reset the number of times of bank activation, denoted as CNT.

In operation S1340, the memory controller 100 may determine whether the RFM command is transmitted as much as the given number of times “N”. According to implementations, the given number of times “N” may be set to one of the positive integers.

When the RFM command is not transmitted as much as the given number of times “N” (No in operation S1340), the memory controller 100 may again perform operation S1310. When the RFM command is transmitted as much as the given number of times “N” (Yes in operation S1340), the memory controller 100 may perform operation S1350.

Referring to operation S1310 to operation S1340 described above, until the RFM command is transmitted as much as the given number of times “N”, the memory controller 100 may operate in the fourth mode without performing the mode register read operation on the mode register 712.

In operation S1350, the memory controller 100 may determine whether the memory device 200 is in the risky situation in association with the row hammer. According to implementations, the memory controller 100 may determine whether the memory device 200 is in the risky situation, through the mode register read operation on the mode register 712.

When the memory device 200 is not in the risky situation (No in operation S1350), the memory controller 100 may perform operation S1210 of FIG. 12.

When the memory device 200 is in the risky situation (Yes in operation S1350), the memory controller 100 may perform operation S1310. In this case, until the RFM command is transmitted as much as the given number of times “N”, the memory controller 100 may operate in the fourth mode without performing the mode register read operation.

Meanwhile, the case where the memory controller 100 performs the mode register read operation on the mode register 712 in both operation S1240 and operation S1350 to determine whether the memory device 200 is in the risky situation is described above as an example. In this case, for example, the memory controller 100 under the operation in the third mode may operate in the fourth mode when the flag data read from the mode register 712 indicates the risky situation (Yes in operation S1240). According to implementations, in this case, as described with reference to FIG. 13, the memory controller 100 may operate in the fourth mode until the RFM command is transmitted as much as the given number of times “N” and may then perform the mode register read operation on the mode register 712. Accordingly, when the flag data does not indicate the risky situation (No in operation S1350), the memory controller 100 may again operate in the third mode.

However, implementations are not limited thereto. For example, in operation S1240, the memory controller 100 may determine whether the risky situation of the memory device 200 occurs, based on the signal received through the alert pin 711; in operation S1350, the memory controller 100 may determine whether the risky situation of the memory device 200 occurs, based on the mode register read operation on the mode register 712. In this case, for example, the memory controller 100 under the operation in the third mode may operate in the fourth mode when the risk signal is applied to the alert pin 711 (Yes in operation S1240). According to implementations, in this case, as described with reference to FIG. 13, the memory controller 100 may operate in the fourth mode until the RFM command is transmitted as much as the given number of times “N” and may then perform the mode register read operation on the mode register 712. When the flag data obtained through the mode register read operation does not indicate the risky situation (No in operation S1350), the memory controller 100 may again operate in the first mode.

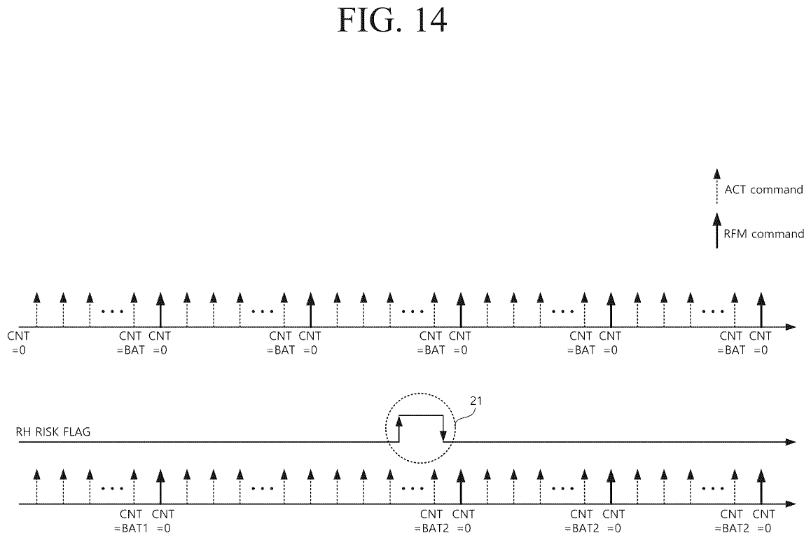

FIG. 14 is a diagram for describing an operation in which a BAT value is adjusted, according to implementations of the present disclosure. The top drawing of FIG. 14 shows an example in which the RFM command is transmitted in a state where the BAT value is fixed, and the bottom drawing of FIG. 10 shows an example in which the RFM command is transmitted in a state where the BAT value is controlled depending on the row hammer risk.

In the bottom drawing of FIG. 14, the row hammer flag data RH RISK FLAG may refer to a signal indicating the row hammer risk of the memory device 200. For example, the row hammer flag data RH RISK FLAG may refer to the flag data signal of the row hammer risk read from the mode register 712 (or a signal of the row hammer risk applied to the alert pin 711). Reference numeral 21 may refer to a flag data signal indicating the risky situation read from the mode register 712 (or the risk signal applied to the alert pin 711).

Referring to the top drawing of FIG. 14, the memory controller 100 may transmit the RFM command whenever the number of times of bank activation, denoted as CNT reaches the BAT. In this case, the BAT may have a fixed value regardless of the row hammer risk. Accordingly, it is understood from the top drawing of FIG. 14 that the RFM command is transmitted at regular intervals (or periodically).

Referring to the bottom drawing of FIG. 14, the memory controller 100 may change the BAT value depending on the row hammer flag data RH RISK FLAG of the memory device 200.

According to implementations, when the memory device 200 is not in the risky situation associated with the row hammer risk, the memory controller 100 may operate in the third mode. For example, until the flag data signal (or risk signal) 21 is obtained, the memory controller 100 may transmit the RFM command when the number of times of bank activation, denoted as CNT, reaches the BAT1.

Meanwhile, when the flag data signal (or risk signal) 21 is obtained, the memory controller 100 under the operation in the third mode may operate in the fourth mode. In the bottom drawing of FIG. 14, a drawing part after the flag data signal (or risk signal) 21 is applied shows the operation in the fourth mode in which the RFM command is transmitted whenever the number of times of bank activation, denoted as CNT, reaches the BAT2. As described above, because the BAT2 is smaller in value than the BAT1, it is confirmed that the transmission frequency of the RFM command corresponding to the case of operating in the fourth mode is higher than the transmission frequency of the RFM command corresponding to the case of operating in the third mode.

According to implementations, in this case, the memory controller 100 may operate in the fourth mode until the RFM command is transmitted as much as the given number of times. In this case, until the number of times of transmission of the RFM command reaches the given number of times, the memory controller 100 may not perform the mode register read operation on the mode register 712.

When the RFM command is transmitted as much as the given number of times while operating in the fourth mode, the memory controller 100 may perform the mode register read operation on the mode register 712. When the flag data read from the mode register 712 through the mode register read operation does not indicate the risky situation, the memory controller 100 may operate in the third mode. When the read flag data indicates the risky situation, the memory controller 100 may again operate in the fourth mode until the RFM command is transmitted as much as the given number of times.

Alternatively, according to implementations, when the RFM command is transmitted as much as the given number of times while operating in the fourth mode, the memory controller 100 may check the signal applied to the alert pin 711 and may determine whether to operate in the third mode based on the checked signal. For example, when the signal applied to the alert pin 711 is checked as being not the risk signal at a point in time when the RFM command is completely transmitted as much as the given number of times, the memory controller 100 may operate in the third mode. When the signal applied to the alert pin 711 is checked as being the risk signal at a point in time when the RFM command is completely transmitted as much as the given number of times, the memory controller 100 may again operate in the fourth mode until the RFM command is transmitted as much as the given number of times.

Below, various implementations in which the BAT value is changed based on temperature information of the memory device 200 will be described with reference to FIGS. 15 to 18.

FIG. 15 is a block diagram of a memory device according to implementations of the present disclosure. A memory device 200D of FIG. 15 may be an implementation of the memory devices 200, 200A, 200B, and 200C of FIGS. 1, 2A, 2B, and 4, but the present disclosure is not limited thereto.

Referring to FIG. 15, the memory device 200D may include the memory cell array 310 and the temperature notification circuit 700B. The memory cell array 310 is described in detail with reference to FIGS. 1 to 3C, and thus, additional description will be omitted to avoid redundancy.

The temperature notification circuit 700B may notify the memory controller 100 of information about a temperature of the memory device 200D. For example, the temperature notification circuit 700B may store temperature information of the memory device 200D. In implementations, the format of the temperature information is not limited as long as the information indicates a temperature range to which the temperature of the memory device 200D belongs.

According to implementations, the temperature notification circuit 700B may be a mode register associated with refresh settings from among mode registers complying with the joint electron device engineering council (JEDEC) DDR5 specification (e.g., an MR4). Information about refresh settings according to the temperature range may be stored in the MR4. Accordingly, information about the temperature range of the memory device 200D may be obtained based on the information stored in the MR4.

However, the temperature notification circuit 700B is not limited to the MR4. The temperature notification circuit 700B may include various memories, which are capable of storing information to be used to identify the temperature range of the memory device 200D like information stored in the MR4, such as a register, a cache memory, and a RAM.

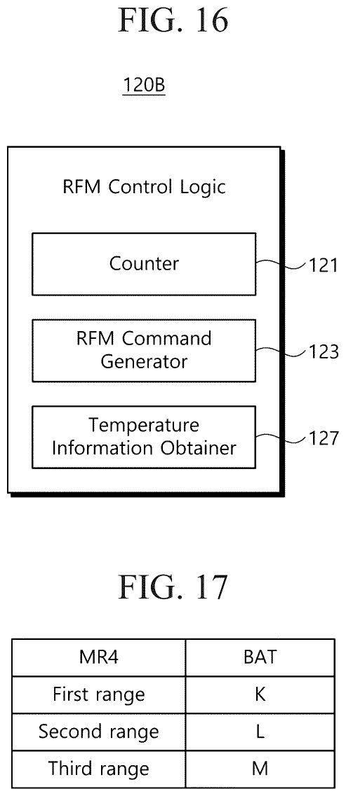

FIG. 16 is a block diagram illustrating RFM control logic according to implementations of the present disclosure. RFM control logic 120B of FIG. 16 which is a component included in the memory controller 100 may be implementations of the RFM control logics 120 and 120A of FIGS. 5A and 6, but the present disclosure is not limited thereto.

Referring to FIG. 16, the RFM control logic 120B may include the counter 121, the RFM command generator 123, and a temperature information obtainer 127.

The counter 121 is described in detail with reference to FIG. 6, and thus, additional description will be omitted to avoid redundancy.

The temperature information obtainer 127 may read information stored in the temperature notification circuit 700B to obtain temperature information of the memory device 200. For example, when the temperature notification circuit 700B is implemented with the MR4, the temperature information obtainer 127 may obtain the temperature information of the memory device 200 through the mode register read operation on the MR4. However, the present disclosure is not limited thereto.

The RFM command generator 123 may generate the RFM command based on the number of times of bank activation counted by the counter 121 or information about a temperature of the memory device 200 obtained through the temperature information obtainer 127 and may transmit the generated RFM command to the memory device 200.

According to implementations, the RFM command generator 123 may adjust the BAT based on the temperature information. For example, when the number of times of bank activation reaches the BAT3 under the condition that the temperature of the memory device 200 is within a first temperature range, the RFM command generator 123 may transmit the RFM command. In implementations, the case where the number of times of bank activation, denoted as CNT, reaches the BAT3 may include the case where the number of times of bank activation, denoted as CNT, is greater in value than the BAT3, in addition to the case where the number of times of bank activation, denoted as CNT, coincides with the BAT3. Also, when the number of times of bank activation reaches the BAT4 under the condition that the temperature of the memory device 200 is within a second temperature range higher than the first temperature range, the RFM command generator 123 may transmit the RFM command. In implementations, the case where the number of times of bank activation, denoted as CNT, reaches the BAT4 may include the case where the number of times of bank activation, denoted as CNT, is greater in value than the BAT4, in addition to the case where the counted number of times of bank activation, denoted as CNT, coincides with the BAT4. Meanwhile, according to embodiment, the BAT3 may be set to be smaller in value than the BAT4.

In detail, in the case of the DDR4 product, as a temperature range becomes lower, the refresh interval time tREFI may become longer. Accordingly, as a temperature range becomes lower, the row hammer refresh opportunities based on the REF command may become lower. The reduced mitigation opportunity for row hammer may be compensated for by making the BAT value become lower as a temperature range decreases. That is, in the above example, because the BAT3 is smaller in value than the BAT4, the transmission frequency of the RFM command in the first temperature range may be higher than the transmission frequency of the RFM command in the second temperature range. Accordingly, the mitigation opportunity reduced depending on a temperature range may be appropriately compensated for.

FIG. 17 is a diagram for describing an example of a BAT value for each temperature range according to implementations of the present disclosure. FIG. 17 shows three temperature ranges stored in the MR4 and BAT values respectively corresponding to the three temperature ranges. For example, the first temperature range may indicate the lowest temperature range among the three temperature ranges, the third temperature range may indicate the highest temperature range, and the second temperature range may be a temperature range between the first temperature range and the third temperature range.

As described above, because the mitigation opportunities for row hammer based on the REF command decrease as a temperature decreases, the BAT values respectively corresponding to the first to third temperature ranges may increase in order of K, L, and M. That is, according to implementations, a value of “L” may be equal to or greater than a value of “K”, and a value of “M” may be equal to or greater than a value of “L”.

The memory controller 100 may obtain temperature information of the memory device 200 through the mode register read operation on the MR4 and may generate and transmit the RFM command by using the BAT value corresponding to the obtained temperature range of the memory device 200.

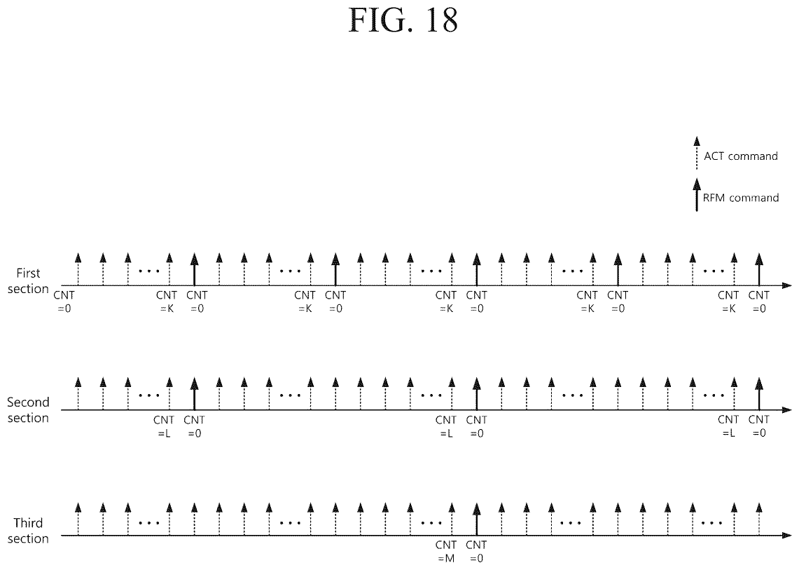

FIG. 18 is a diagram for describing an operation in which a BAT value is adjusted, according to implementations of the present disclosure. FIG. 18 shows an RFM command transmission operation corresponding to each of the first to third temperature ranges of FIG. 17.

Referring to FIG. 18, when the number of times of bank activation reaches “K” under the condition that the temperature range of the memory device 200 is the first temperature range, the memory controller 100 may transmit the RFM command. Also, when the number of times of bank activation reaches “L” under the condition that the temperature range of the memory device 200 is the second temperature range, the memory controller 100 may transmit the RFM command. Also, when the number of times of bank activation reaches “M” under the condition that the temperature range of the memory device 200 is the third temperature range, memory controller 100 may transmit the RFM command. In implementations, the case where the number of times of bank activation, denoted as CNT, reaches the specific number of times (i.e., K, L, or M) may include the case where the number of times of bank activation, denoted as CNT, is greater than the corresponding number of times (i.e., K, L, or M), in addition to the case where the number of times of bank activation, denoted as CNT, coincides with the corresponding number of times (i.e., K, L, or M).

In this case, because the BAT values of the temperature ranges increase in order of K, L, and M, the memory controller 100 may transmit the RFM command with a relatively higher frequency (or at a shorter interval/more frequently) as it goes toward a relatively low temperature range.

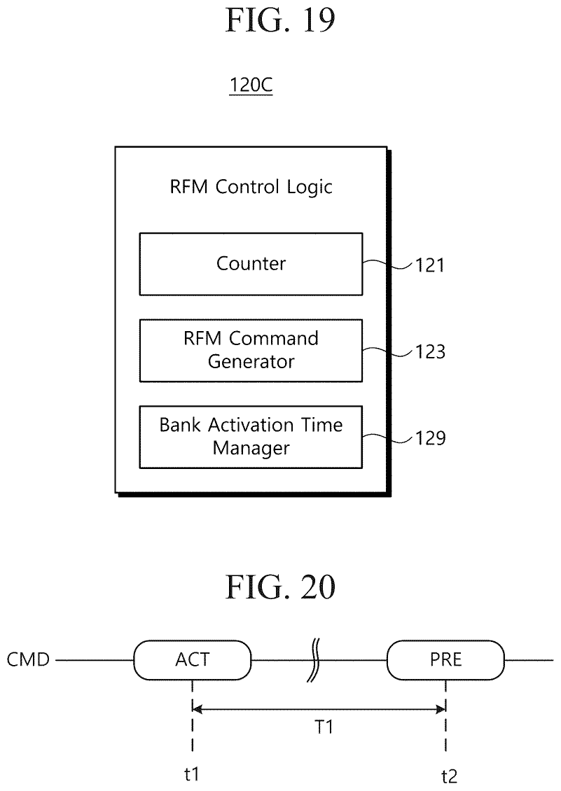

Below, various implementations in which the RFM command is transmitted in consideration of the bank activation time will be described with reference to FIGS. 19 to 23.

FIG. 19 is a block diagram of RFM control logic according to implementations of the present disclosure, and FIG. 20 is a diagram for describing a bank activation time according to implementations of the present disclosure. RFM control logic 120C of FIG. 19 which is a component included in the memory controller 100 may be implementations of the RFM control logics 120, 120A, and 120B of FIGS. 5A, 6, and 16, but the present disclosure is not limited thereto.

Referring to FIG. 19, the RFM control logic 120C may include the counter 121, the RFM command generator 123, and a bank activation time manager 129.

The counter 121 may count the number of times of bank activation.

According to implementations, the counter 121 may count the number of times of bank activation by increasing the number of times of bank activation as much as “1” whenever the ACT command is transmitted to the memory device 200, without consideration of the bank activation time.

Meanwhile, according to implementations, the counter 121 may count the number of times of bank activation in consideration of the bank activation time. For example, the counter 121 may convert the bank activation time into the number of times of bank activation to count the number of times of bank activation. In this case, when the counter 121 counts the number of times of bank activation, the counter 121 may increase a value differently depending on the bank activation time which is based on the corresponding ACT command. In implementations, information about the bank activation time based on the ACT command may be obtained through the bank activation time manager 129, but the present disclosure is not limited thereto.

In implementations, when the bank activation time based on the first ACT command is equal to or smaller than the reference time, the counter 121 may increase the number of times of activation according to the transmission of the first ACT command as much as a first value (e.g., “1”). Also, when the bank activation time based on the second ACT command exceeds the reference time, the counter 121 may increase the number of times of activation according to the transmission of the second ACT command as much as a second value (e.g., “2”).

In this case, according to implementations, when the counter 121 counts the number of times of bank activation, the counter 121 may increase a value corresponding to the bank activation time at once. For example, when the bank activation time based on the ACT command exceeds the reference time, the counter 121 may increase the number of times of activation as much as “2” at once.

Alternatively, according to implementations, when the counter 121 counts the number of times of bank activation, the counter 121 may increase a value corresponding to the bank activation time stepwise. For example, the counter 121 may increase the number of times of bank activation as much as “1” when the ACT command is transmitted. Afterwards, the counter 121 may check the bank activation time; when the bank activation time exceeds the reference time, the counter 121 may additionally increase the number of times of bank activation as much as “1”.

Meanwhile, for convenience of description, an example in which the bank activation time is divided into two sections based on one reference time is described above. However, of course, implementations are not limited thereto. The bank activation time may be divided into three or more sections depending on implementations. For example, the bank activation time may be divided into three sections based on a first reference time and a second reference time. In implementations, the second reference time may be longer than the first reference time.

In this case, when the bank activation time based on the first ACT command is equal to or smaller than the first reference time, the counter 121 may increase the number of times of activation according to the transmission of the first ACT command as much as the first value (e.g., “1”). Also, when the bank activation time based on the second ACT command exceeds the first reference time and is equal to or smaller than the second reference time, the counter 121 may increase the number of times of activation according to the transmission of the second ACT command as much as the second value (e.g., “2”). Also, when the bank activation time based on the third ACT command exceeds the second reference time, the counter 121 may increase the number of times of activation according to the transmission of the third ACT command as much as a third value (e.g., “3”).

The bank activation time manager 129 may manage the bank activation time associated with the ACT command which the memory controller 100 transmits.

According to implementations, the bank activation time manager 129 may obtain the bank activation time. For example, as illustrated in FIG. 20, a time duration T1 from a first point in time t1 when the ACT command is transmitted to a second point in time t2 when the PRE command is transmitted may be the bank activation time based on the ACT command. When the ACT command is transmitted, the bank activation time manager 129 may calculate (or measure) a time duration between a point in time when the ACT command is transmitted and a point in time when the PRE command following the ACT command is transmitted and may obtain the bank activation time which is based on the corresponding ACT command.

Meanwhile, according to implementations, the bank activation time manager 129 may sum the bank activation time. For example, whenever the ACT command is transmitted, the bank activation time manager 129 may obtain the bank activation time which is based on each ACT command and may accumulate the obtained bank activation time.

The RFM command generator 123 may generate the RFM command based on the number of times of bank activation counted by the counter 121 and the bank activation time managed by the bank activation time manager 129 and may transmit the generated RFM command to the memory device 200.

According to implementations, when the number of times of bank activation reaches the BAT, the RFM command generator 123 may transmit the RFM command to the memory device 200. In this case, the RFM command generator 123 may determine whether the number of times of bank activation reaches the BAT, by using the number of times of bank activation counted in consideration of the bank activation time. In this case, as the ACT command having the bank activation time exceeding the reference time is more transmitted, the number of times of bank activation may increase more quickly. This may mean that the RFM command is transmitted more frequently.

Meanwhile, according to implementations, when the number of times of bank activation reaches the BAT or the summed bank activation time reaches the BATT, the RFM command generator 123 may transmit the RFM command to the memory device 200. In this case, the RFM command generator 123 may determine whether the number of times of bank activation reaches the BAT, by using the number of times of bank activation counted without consideration of the bank activation time. In this case, even though the number of times of bank activation does not reach the BAT, when the bank activation time reaches the BATT, the RFM command may be transmitted.

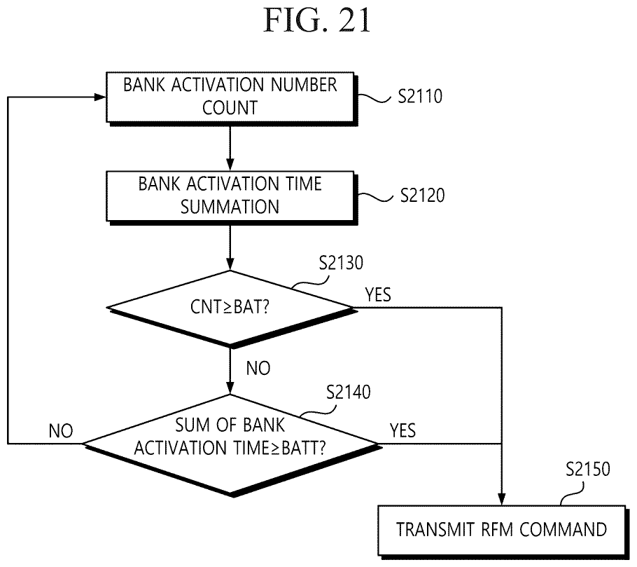

FIG. 21 is a flowchart illustrating an operating method of a memory controller according to implementations of the present disclosure. FIG. 21 shows an implementation in which the RFM command is transmitted based on the threshold BAT associated with the number of times of bank activation and the threshold BATT associated with the bank activation time. In describing FIG. 21, the description which is given above will be omitted.

Referring to FIG. 21, in operation S2110, the memory controller 100 may count the number of times of bank activation. For example, when the ACT command is transmitted, the memory controller 100 may increase the number of times of bank activation, denoted as CNT, as much as “1”.

In operation S2120, the memory controller 100 may sum the bank activation time. For example, the memory controller 100 may obtain the ACT command-based bank activation time and may accumulate the obtained bank activation time.

In operation S2130, the memory controller 100 may determine whether the counted number of times of bank activation, denoted as CNT, reaches the BAT. In this case, the case where the counted number of times of bank activation, denoted as CNT, reaches the BAT may include the case where the counted number of times of bank activation, denoted as CNT, is greater in value than the BAT, in addition to the case where the counted number of times of bank activation, denoted as CNT, coincides with the BAT.

Accordingly, according to implementations, the memory controller 100 may determine whether the counted number of times of bank activation, denoted as CNT, reaches the BAT, by determining whether the counted number of times of bank activation, denoted as CNT, is equal to or greater than the BAT.

When the counted number of times of bank activation, denoted as CNT, is equal to or greater than the BAT, that is, when the counted number of times of bank activation, denoted as CNT, reaches the BAT (Yes in operation S2130), the memory controller 100 may perform operation S2150. In operation S2150, the memory controller 100 may transmit the RFM command to the memory device 200.

When the number of times of bank activation, denoted as CNT, is smaller than the BAT, that is, when the number of times of bank activation, denoted as CNT, does not reach the BAT (No in operation S2130), the memory controller 100 may perform operation S2140. In operation S2140, the memory controller 100 may determine whether the number of times of bank activation summed up to now, denoted as CNT, reaches the BATT. In implementations, the case where the summed number of times of bank activation reaches the BATT may include the case where the summed number of times of bank activation is greater in value than the BATT, in addition to the case where the summed number of times of bank activation coincides with the BATT.

Accordingly, according to implementations, the memory controller 100 may determine whether the summed number of times of bank activation reaches the BATT, by determining whether the summed number of times of bank activation is equal to or greater than the BATT.

When the summed number of times of bank activation is equal to or greater than the BATT, that is, when the summed number of times of bank activation reaches the BATT (Yes in operation S2140), the memory controller 100 may perform operation S2150. In operation S2150, the memory controller 100 may transmit the RFM command to the memory device 200. In this case, the memory controller 100 may reset the number of times of bank activation, denoted as CNT.

When the summed number of times of bank activation is smaller than the BATT, that is, when the summed number of times of bank activation does not reach the BATT (No in operation S2140), the memory controller 100 may perform operation S2110.

Meanwhile, the case where operation S2120 is performed after operation S2110 is performed and operation S2140 is performed after operation S2130 is performed is illustrated in FIG. 21 as an example, but the present disclosure is not limited thereto. According to implementations, operation S2120 may be performed prior to operation S2110. Also, operation S2140 may be performed prior to operation S2130. In the case where operation S2140 is performed prior to operation S2130, operation S2130 may be performed when the summed number of times of bank activation does not reach the BATT, and operation S2110 may be again performed when the summed number of times of bank activation does not reach the BATT.

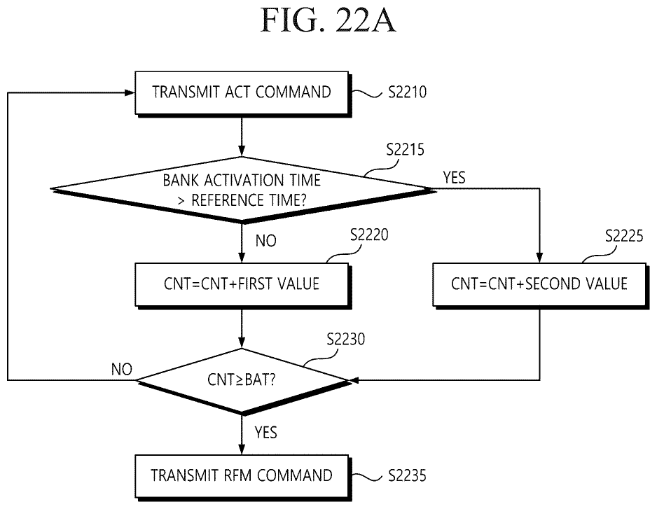

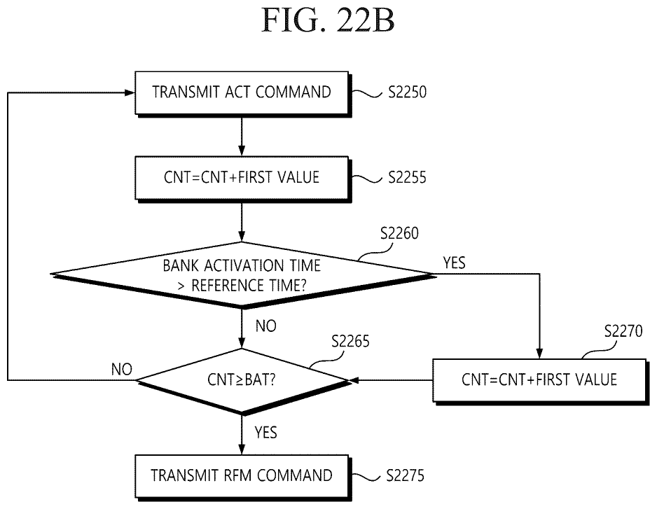

FIGS. 22A and 22B are flowcharts illustrating operating methods of a memory controller according to implementations of the present disclosure. FIGS. 22A and 22B show implementations in which the number of times of bank activation is counted in consideration of the bank activation time. In describing FIGS. 22A and 22B, the description which is given above will be omitted or simplified.

Referring to FIG. 22A, in operation S2210, the memory controller 100 may transmit the ACT command to the memory device 200.

In operation S2215, the memory controller 100 may determine whether the bank activation time based on the ACT command exceeds the reference time.

When the bank activation time is equal to or smaller than the reference time (No in operation S2215), the memory controller 100 may perform operation S2220. Also, when the bank activation time exceeds the reference time (Yes in operation S2215), the memory controller 100 may perform operation S2225.

In operation S2220, the memory controller 100 may increase the number of times of bank activation, denoted as CNT, as much as the first value. In implementations, the first value may be “1”, but the present disclosure is not limited thereto.

In operation S2225, the memory controller 100 may increase the number of times of bank activation, denoted as CNT, as much as the second value. In implementations, the second value may be greater than the first value. For example, when the first value is “1”, the second value may be “2”. However, the present disclosure is not limited thereto.

In operation S2230, the memory controller 100 may determine whether the counted number of times of bank activation, denoted as CNT, reaches the BAT. In this case, according to implementations, the memory controller 100 may determine whether the counted number of times of bank activation, denoted as CNT, reaches the BAT, by determining whether the counted number of times of bank activation, denoted as CNT, is equal to or greater than the BAT.

When the counted number of times of bank activation, denoted as CNT, is equal to or greater than the BAT, that is, when the counted number of times of bank activation, denoted as CNT, reaches the BAT (Yes in operation S2230), the memory controller 100 may perform operation S2235. In operation S2235, the memory controller 100 may transmit the RFM command to the memory device 200. In this case, the memory controller 100 may reset the number of times of bank activation, denoted as CNT.

Meanwhile, when the number of times of bank activation, denoted as CNT, is smaller than the BAT, that is, when the number of times of bank activation, denoted as CNT, does not reach the BAT (No in operation S2230), the memory controller 100 may again perform operation S2210.

According to FIG. 22A, when the memory controller 100 counts the number of times of bank activation, the memory controller 100 may increase a value corresponding to the bank activation time at once.

Meanwhile, referring to FIG. 22B, in operation S2250, the memory controller 100 may transmit the ACT command to the memory device 200.

In operation S2255, the memory controller 100 may increase the number of times of based on the ACT command bank activation, denoted as CNT, as much as the first value. In implementations, the first value may be “1”, but the present disclosure is not limited thereto.

In operation S2260, the memory controller 100 may determine whether the bank activation time based on the ACT command exceeds the reference time.

When the bank activation time is equal to or smaller than the reference time (No in operation S2260), the memory controller 100 may perform operation S2265. Also, when the bank activation time exceeds the reference time (Yes in operation S2260), the memory controller 100 may perform operation S2270.

In operation S2270, the memory controller 100 may additionally increase the number of times of bank activation, denoted as CNT, as much as the first value and may then perform operation S2265.

In operation S2265, the memory controller 100 may determine whether the counted number of times of bank activation, denoted as CNT, reaches the BAT. In this case, according to an implementations, the memory controller 100 may determine whether the counted number of times of bank activation, denoted as CNT, reaches the BAT, by determining whether the counted number of times of bank activation, denoted as CNT, is equal to or greater than the BAT.

When the counted number of times of bank activation, denoted as CNT, is equal to or greater than the BAT, that is, when the counted number of times of bank activation, denoted as CNT, reaches the BAT (Yes in operation S2265), the memory controller 100 may perform operation S2275. In operation S2275, the memory controller 100 may transmit the RFM command to the memory device 200. In this case, the memory controller 100 may reset the number of times of bank activation, denoted as CNT.

Meanwhile, when the number of times of bank activation, denoted as CNT, is smaller than the BAT, that is, when the number of times of bank activation, denoted as CNT, does not reach the BAT (No in operation S2265), the memory controller 100 may again perform operation S2250.

Referring to FIG. 22B, when the memory controller 100 counts the number of times of bank activation, the memory controller 100 may increase a value corresponding to the bank activation time stepwise.

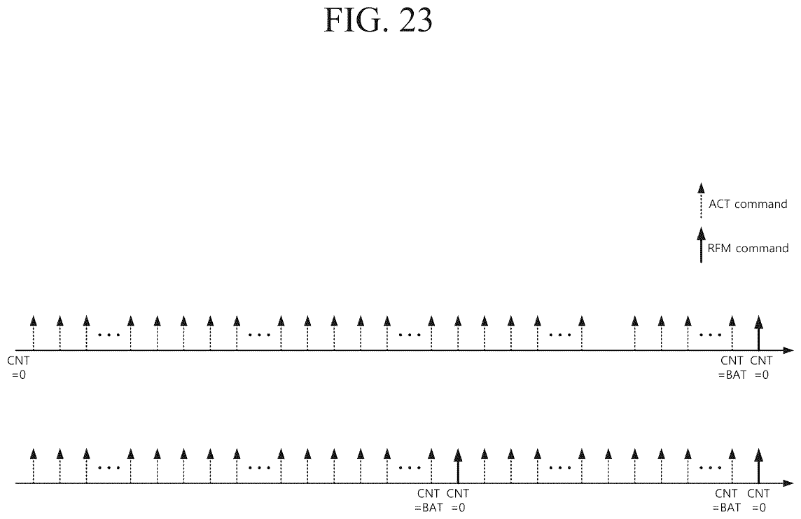

FIG. 23 is a diagram for describing an operation in which the RFM command is transmitted in consideration of the bank activation time, according to implementations of the present disclosure.

The top drawing of FIG. 23 shows an example in which the RFM command is transmitted without consideration of the bank activation time, and the bottom drawing of FIG. 23 shows an example in which the RFM command is transmitted in consideration of the bank activation time. In implementations, the two examples are provided under the assumption that ACT commands having the bank activation time exceeding the reference time are transmitted as much as the same number of times.

Referring to the top drawing of FIG. 23, the memory controller 100 may increase the number of times of bank activation, denoted as CNT, as much as “1” whenever the ACT command is transmitted and may transmit the RFM command to the memory device 200 when the counted number of times of bank activation, denoted as CNT, reaches the BAT.

Referring to the bottom drawing of FIG. 23, the memory controller 100 may convert the bank activation time into the number of times of bank activation so as to be added to the number of times of bank activation. For example, when the ACT command having the bank activation time exceeding the reference time is transmitted to the memory device 200, the memory controller 100 may increase the number of times of bank activation according to the corresponding ACT command as much as “2”. In this case, as the ACT command having the bank activation time exceeding the reference time is transmitted more often, the number of times of bank activation may increase more quickly. This may mean that the RFM command is transmitted more frequently. Accordingly, it may be possible to cope with the issue due to the PGE phenomenon.

Meanwhile, according to implementations, the memory controller 100 may determine whether to transmit the RFM command in consideration of both the threshold BAT associated with the number of times of bank activation and the threshold BATT associated with the bank activation time. In this case, even though the number of times of bank activation does not reach the BAT, when the bank activation time reaches the BATT, the RFM command may be transmitted. Accordingly, it may be possible to cope with the issue due to the PGE phenomenon.

According to the above implementations of the present disclosure, the transmission frequency of the RFM command may be variably controlled depending on a situation of a memory device. Accordingly, the efficiency of bandwidth of a memory system or the performance of the memory system may be improved.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to implementations thereof, it will be apparent to those of ordinary skill in the art that various changes and modifications may be made thereto without departing from the spirit and scope of the present disclosure as set forth in the following claims.

What is claimed is:

1. A memory system comprising:
a memory device including a memory cell array and a notification circuit; and
a memory controller configured to transmit a refresh management (RFM) command to the memory device, based on a number of occurrences of bank activation of a bank included in the memory cell array reaching a threshold,
wherein the memory controller is configured to control a transmission frequency of the RFM command, based on a notification obtained through the notification circuit, and
wherein the notification comprises at least one of risk information related to a row hammer risk for rows included in the bank or temperature information of the memory device, wherein the temperature information comprises a current temperature of the memory device.

2. The memory system of claim 1, wherein the bank includes:
a plurality of rows arranged in a row direction; and
a plurality of count cells configured to store count data associated with the number of occurrences of activation of each of the plurality of rows,
wherein risk information related to the row hammer risk indicates that the count data reached a reference count.

3. The memory system of claim 2, wherein the notification circuit includes:
at least one of:
an alert pin configured to transmit a risk signal in response to the count data stored in at least one count cell among the plurality of count cells reaching the reference count to indicate a risky situation, or
a first register configured to store flag data in response to the count data stored in at least one count cell among the plurality of count cells reaching the reference count to indicate the risky situation.

4. The memory system of claim 3, wherein the memory controller is configured to:
obtain the row hammer risk based on the flag data stored in the first register or the risk signal transmitted by the alert pin.

5. The memory system of claim 4, wherein the memory controller is configured to:
set an operation mode to one of a first mode or a second mode based on the row hammer risk,
wherein, in the first mode, the memory controller is configured to maintain operation without transmitting the RFM command irrespective of the number of occurrences of bank activation, and
wherein, in the second mode, the memory controller is configured to transmit the RFM command based on the number of occurrences of bank activation reaching the threshold.

6. The memory system of claim 5, wherein the memory controller is configured to:
set the operation mode to the second mode based on the flag data comprising first data indicative of the risky situation; and
otherwise set the operation mode to the first mode.

7. The memory system of claim 6, wherein the memory controller is configured to:
perform a read operation on the first register to obtain the row hammer risk based on the number of occurrences of bank activation reaching the threshold.

8. The memory system of claim 6, wherein the memory controller is configured to:
perform, in the first mode, a read operation on the first register to obtain the row hammer risk based on the number of occurrences of bank activation reaching the threshold,
switch the operation mode from the first mode to the second mode based on obtaining the flag data indicating the risky situation, and
switch the operation mode from the second mode back to the first mode in response to transmitting a set number of the RFM commands to perform the read operation on the first register.

9. The memory system of claim 5, wherein the memory controller is configured to:
set the operation mode to the second mode based on the risk signal being applied through the alert pin; and
otherwise set the operation mode to the first mode.

10. The memory system of claim 9, wherein the memory controller is configured to:
perform a read operation on the first register after operating in the second mode until the RFM command is transmitted no more than a predefined number of times, based on the risk signal being applied through the alert pin while the memory controller operates in the first mode.

11. The memory system of claim 4, wherein the memory controller is configured to:
set an operation mode to one of a third mode or a fourth mode based on the row hammer risk,
wherein, in the third mode, the memory controller is configured to transmit the RFM command based on the number of occurrences of bank activation reaching a first threshold,
wherein, in the fourth mode, the memory controller is configured to transmit the RFM command based on the number of occurrences of bank activation reaching a second threshold, and
wherein the second threshold is smaller in value than the first threshold.

12. The memory system of claim 11, wherein the memory controller is configured to:
set the operation mode to the fourth mode based on the risk signal being applied through the alert pin or based on obtaining the flag data indicative of the risky situation through a read operation on the first register while the memory controller operates in the third mode.

13. The memory system of claim 12, wherein the memory controller is configured to:
perform the read operation on the first register based on the RFM command being transmitted no more than a predefined number of times while the memory controller operates in the fourth mode; and
otherwise operate in the third mode.

14. The memory system of claim 1, wherein the notification circuit includes:
a second register configured to store temperature information of the memory device, and
wherein the memory controller is configured to:
obtain the temperature information based on a read operation of the second register; and
adjust the threshold based on the obtained temperature information.

15. The memory system of claim 14, wherein the memory device is configured to operate in a first refresh interval time for a first temperature range and is configured to operate in a second refresh interval time that is shorter than the first refresh interval time for a second temperature range,
wherein the memory controller is configured to:
transmit the RFM command based on the number of occurrences of bank activation reaching a third threshold in the first temperature range; and
transmit the RFM command based on the number of occurrences of bank activation reaching a fourth threshold in the second temperature range, and
wherein the third threshold is smaller in value than the fourth threshold.

16. The memory system of claim 1, wherein the memory controller is configured to:
count, in response to an activate command being transmitted to the bank, the number of occurrences of bank activation;
sum a bank activation time of the bank, which is based on the activate command transmitted to the bank; and
transmit the RFM command based on the number of occurrences of bank activation reaching the threshold or based on the summed bank activation time reaching a time threshold.

17. The memory system of claim 16, wherein the memory controller is configured to:
increase the number of occurrences of bank activation as much as a first value based on the bank activation time being equal to or smaller than a reference time; and
increase the number of occurrences of bank activation as much as a second value greater than the first value based on the bank activation time exceeding the reference time.

18. An operating method of a memory controller which controls a memory device, the method comprising:
transmitting a refresh management (RFM) command to the memory device based on a number of occurrences of bank activation of a bank of the memory device reaching a threshold;
obtaining a notification including at least one of information about a row hammer risk of each of rows included in the bank of the memory device or temperature information about the memory device, wherein the temperature information comprises a temperature range of the memory device; and
controlling a transmission frequency of the RFM command based on the notification.

19. The method of claim 18, wherein controlling the transmission frequency of the RFM command includes:
selectively transmitting the RFM command based on the notification or adjusting the threshold based on the notification.

20. A memory device comprising:
a memory cell array including a bank;
a row hammer management circuit; and
a notification circuit including at least one of an alert pin or a register,
wherein the bank includes:
a plurality of rows arranged in a row direction; and
a plurality of count cells configured to store count data associated with a number of occurrences of activation of each of the plurality of rows, and
wherein the row hammer management circuit is configured to:
manage count data for each of the plurality of rows; and
store flag data indicating a risky situation in the register and apply a risk signal indicating the risky situation to the alert pin, based on the count data stored in at least one of the plurality of count cells reaching a reference count.
